(19) United States
(12) Patent Application Publication
(10) Pub. No.: US 2022/0352384 A1
(43) Pub. Date: Nov. 3, 2022

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Masashi OOTA, Atsugi (JP); Yoshinori ANDO, Atsugi (JP); Shuhei NAGATSUKA, Atsugi (JP); Tatsuki KOSHIDA, Nanao (JP); Satoru OHSHITA, Atsugi (JP); Ryota HODO, Atsugi (JP); Kazuki TSUDA, Atsugi (JP); Akio SUZUKI, Atsugi (JP)

(21) Appl. No.: 17/760,836

(22) PCT Filed: Sep. 11, 2020
(86) PCT No.: PCT/IB2020/058438

§ 371 Date: Mar. 16, 2022

(30) Foreign Application Priority Data
Sep. 20, 2019 (JP) 2019-171143

(51) Int. Cl. H01L 29/786; H01L 27/108; H01L 29/66

(52) U.S. Cl. CPC H01L 29/78693; H01L 29/78696; H01L 27/10808; H01L 27/10873; H01L 29/66742; H01L 27/10897; H01L 27/10855

(57) ABSTRACT

A semiconductor device that is suitable for high integration is provided. A first layer provided with a first transistor including an oxide semiconductor, over a substrate; a second layer over the first layer; a third layer provided with a second transistor including an oxide semiconductor, over the second layer; a fourth layer between the first layer and the second layer; and a fifth layer between the second layer and the third layer are included. The total internal stress of the first layer and the total internal stress of the third layer act in a first direction, the total internal stress of the second layer acts in the direction opposite to the first direction, and the fourth layer and the fifth layer each include a film having a barrier property.

### TECHNICAL FIELD

One embodiment of the present invention relates to a semiconductor device and a method for manufacturing the semiconductor device. One embodiment of the present invention relates to a semiconductor wafer, a module, and an electronic device.

Note that in this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, or the like), a projection device, a lighting device, an electro-optical device, a power storage device, a storage device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Another embodiment of the present invention relates to a process, a machine, manufacture, or a composition of matter.

### BACKGROUND ART

A technique by which a transistor is formed using a semiconductor thin film formed over a substrate having an insulating surface has been attracting attention. The transistor is applied to a wide range of electronic devices, such as an integrated circuit (IC) and an image display device (also simply referred to as a display device). A silicon-based semiconductor material is widely known as a semiconductor thin film applicable to the transistor; in addition, an oxide semiconductor has attracted attention as another material.

A CAAC (c-axis aligned crystalline) structure and an nc (nanocrystalline) structure, which are neither single crystal nor amorphous, have been found in an oxide semiconductor (see Non-Patent Document 1 and Non-Patent Document 2).

Non-Patent Document 1 and Non-Patent Document 2 each disclose a technique for forming a transistor with the use of an oxide semiconductor having a CAAC structure.

### REFERENCE

### Non-Patent Document

[Non-Patent Document 1] S. Yamazaki et al., “SID Symposium Digest of Technical Papers”, 2012, volume 43, issue 1, p. 183-186

[Non-Patent Document 2] S. Yamazaki et al., “Japanese Journal of Applied Physics”, 2014, volume 53, Number 4S, p. 04ED18-1-04ED18-10

### SUMMARY OF THE INVENTION

### Problems to be Solved by the Invention

An object of one embodiment of the present invention is to provide a highly reliable semiconductor device. Another object of one embodiment of the present invention is to provide a semiconductor device with favorable electrical characteristics. Another object of one embodiment of the present invention is to provide a semiconductor device with a high on-state current. Another object of one embodiment of the present invention is to provide a semiconductor device that can be miniaturized or highly integrated. One object of one embodiment of the present invention is to provide a semiconductor device with low power consumption.

Note that the description of these objects does not preclude the existence of other objects. One embodiment of the present invention does not have to achieve all these objects. Other objects are apparent from and can be derived from the description of the specification, the drawings, the claims, and the like.

### Means for Solving the Problems

One embodiment of the present invention includes a first layer provided with a first transistor including an oxide semiconductor, over a substrate; a second layer over the first layer; and a third layer provided with a second transistor including an oxide semiconductor, over the second layer. The total internal stress of the first layer and the total internal stress of the third layer act in a first direction, and the total internal stress of the second layer acts in a direction opposite to the first direction.

One embodiment of the present invention includes a first layer provided with a first transistor including an oxide semiconductor, over a substrate; a second layer over the first layer; a third layer provided with a second transistor including an oxide semiconductor, over the second layer; a fourth layer between the first layer and the second layer; and a fifth layer between the second layer and the third layer. The total internal stress of the first layer and the total internal stress of the third layer act in a first direction, the total internal stress of the second layer acts in a direction opposite to the first direction, and the fourth layer and the fifth layer each include a film having a barrier property.

In the above, the total internal stress of the fourth layer and the total internal stress of the fifth layer act in the first direction.

In the above, the film having the barrier property inhibits diffusion of hydrogen and an impurity.

In the above, the first layer is sealed with the fourth layer, and the third layer is sealed with the fifth layer.

In the above, the second layer includes a conductor functioning as a wiring.

In the above, the oxide semiconductor is an In—Ga—Zn oxide.

### Effect of the Invention

According to one embodiment of the present invention, a highly reliable semiconductor device can be provided. According to one embodiment of the present invention, a semiconductor device with favorable electrical characteristics can be provided. According to one embodiment of the present invention, a semiconductor device with a high on-state current can be provided. According to one embodiment of the present invention, a semiconductor device that can be miniaturized or highly integrated can be provided. According to one embodiment of the present invention, a semiconductor device with low power consumption can be provided.

Note that the description of these effects does not preclude the existence of other effects. One embodiment of the present invention does not have to have all these effects. Other effects will be apparent from and can be derived from the description of the specification, the drawings, the claims, and the like.

### BRIEF DESCRIPTION OF THE DRAWINGS

FIG. 1A and FIG. 1B are cross-sectional views of a semiconductor device of one embodiment of the present invention.

FIG. 2A, FIG. 2B, FIG. 2C, and FIG. 2D are a top view and cross-sectional views of a semiconductor device of one embodiment of the present invention.

FIG. 3A, FIG. 3B, FIG. 3C, and FIG. 3D are a top view and cross-sectional views illustrating a method for manufacturing a semiconductor device of one embodiment of the present invention.

FIG. 4A, FIG. 4B, FIG. 4C, and FIG. 4D are a top view and cross-sectional views illustrating the method for manufacturing a semiconductor device of one embodiment of the present invention.

FIG. 5A, FIG. 5B, FIG. 5C, and FIG. 5D are a top view and cross-sectional views illustrating the method for manufacturing a semiconductor device of one embodiment of the present invention.

FIG. 6A, FIG. 6B, FIG. 6C, and FIG. 6D are a top view and cross-sectional views illustrating the method for manufacturing a semiconductor device of one embodiment of the present invention.

FIG. 7A, FIG. 7B, FIG. 7C, and FIG. 7D are a top view and cross-sectional views illustrating the method for manufacturing a semiconductor device of one embodiment of the present invention.

FIG. 8A, FIG. 8B, FIG. 8C, and FIG. 8D are a top view and cross-sectional views illustrating the method for manufacturing a semiconductor device of one embodiment of the present invention.

FIG. 9A, FIG. 9B, FIG. 9C, and FIG. 9D are a top view and cross-sectional views illustrating the method for manufacturing a semiconductor device of one embodiment of the present invention.

FIG. 10A, FIG. 10B, and FIG. 10C are cross-sectional views and a top view of a semiconductor device of one embodiment of the present invention.

FIG. 11A, FIG. 11B, FIG. 11C, and FIG. 11D are cross-sectional views and a top view of a semiconductor device of one embodiment of the present invention.

FIG. 12 is a cross-sectional view illustrating a structure of a memory device of one embodiment of the present invention.

FIG. 13 is a cross-sectional view illustrating a structure of a memory device of one embodiment of the present invention.

FIG. 14 is a cross-sectional view illustrating a structure of a memory device of one embodiment of the present invention.

FIG. 15A and FIG. 15B are a block diagram and a perspective view illustrating a structure example of a memory device of one embodiment of the present invention.

FIG. 16A, FIG. 16B, FIG. 16C, FIG. 16D, FIG. 16E, FIG. 16F, FIG. 16G, and FIG. 16H are circuit diagrams illustrating structure examples of a memory device of one embodiment of the present invention.

FIG. 17A and FIG. 17B are schematic diagrams of a semiconductor device of one embodiment of the present invention.

FIG. 18A, FIG. 18B, FIG. 18C, FIG. 18D, and FIG. 18E are schematic diagrams of a memory device of one embodiment of the present invention.

FIG. 19A, FIG. 19B, FIG. 19C, FIG. 19D, FIG. 19E, FIG. 19F, FIG. 19G, and FIG. 19H illustrates electronic devices of embodiments of the present invention.

FIG. 20A and FIG. 20B show cross-sectional STEM observation results of a sample in the example.

FIG. 21 shows a cross-sectional STEM observation result of the sample in the example.

FIG. 22A and FIG. 22B show I_{d}-V_{g} measurement results of transistors included in the sample in the example.

FIG. 23A and FIG. 23B show influence of a change in the threshold values of the transistors included in the sample in the example upon the field-effect mobility (μ_{FEs}) of each transistor 200.

FIG. 24A and FIG. 24B show I_{d}-V_{g} measurement results and mobility measurement results of the transistors included in the sample in the example.

FIG. 25 shows measurement results of off-leakage currents of the transistor included in the sample in the example.

FIG. 26A and FIG. 26B show write speeds of the transistors included in the sample in Example.

FIG. 27 shows write operation at the time when the transistor included in the sample in the example functions as a multilevel memory and shows results of a retention test.

FIG. 28 shows a write time and an erase time of the transistor included in the sample in the example in multilevel operation.

FIG. 29 shows results of a rewrite endurance test of the transistor included in the sample in the example in binary operation.

FIG. 30 shows the cutoff frequency f_{T} of the transistor included in the sample in the example.

### MODE FOR CARRYING OUT THE INVENTION

Hereinafter, embodiments are described with reference to the drawings. Note that the embodiments can be implemented with many different modes, and it is readily understood by those skilled in the art that modes and details thereof can be changed in various ways without departing from the spirit and scope thereof. Thus, the present invention should not be interpreted as being limited to the description of the embodiments below.

In the drawings, the size, the layer thickness, or the region is exaggerated for clarity in some cases. Therefore, they are not limited to the illustrated scale. Note that the drawings schematically illustrate ideal examples, and embodiments of the present invention are not limited to shapes, values, and the like shown in the drawings. For example, in the actual manufacturing process, a layer, a resist mask, or the like might be unintentionally reduced in size by treatment such as etching, which might not be reflected in the drawings for easy understanding of the invention. Furthermore, in the drawings, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases.

Furthermore, especially in a top view (also referred to as a “plan view”), a perspective view, or the like, the description of some components might be omitted for easy understanding of the invention. In addition, some hidden lines and the like might not be shown.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relation between components with reference to drawings. The positional relationship between components is changed as appropriate in accordance with a direction in which the components are described. Thus, without limitation to terms described in this specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of current is changed in circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, and the average value in a channel formation region.

The channel width refers to, for example, the length of a channel formation region in a direction perpendicular to a channel length direction in a region where a semiconductor (or a portion where current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, and the average value in a channel formation region.

Note that in this specification and the like, depending on the transistor structure, a channel width in a region where a channel is actually formed (hereinafter also referred to as an “effective channel width”) is sometimes different from a channel width shown in a top view of a transistor (hereinafter also referred to as an “apparent channel width”). For example, in a transistor whose gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is increased in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that values of a channel length, a channel width, an effective channel width, an apparent channel width, and the like can be determined, for example, by analyzing a cross-sectional TEM image and the like.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. Entry of an impurity may cause oxygen vacancies in an oxide semiconductor, for example.

Note that in this specification and the like, silicon oxynitride is a material that contains more oxygen than nitrogen in its composition. Moreover, silicon nitride oxide is a material that contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle of greater than or equal to −10° and less than or equal to 10°. Accordingly, the case where the angle is greater than or equal to −5° and less than or equal to 5° is also included. In addition, “substantially parallel” indicates a state where the angle formed between two straight lines is greater than or equal to −30° and less than or equal to 30°. In addition, “perpendicular” indicates a state where the angle formed between two straight lines is greater than or equal to 80° and less than or equal to 100°. Accordingly, the case where the angle is greater than or equal to 85° and less than or equal to 95° is also included. In addition, “substantially perpendicular” indicates a state where the angle formed between two straight lines is greater than or equal to 60° and less than or equal to 120°. [Reference Numerals]

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be called a transistor including a metal oxide or an oxide semiconductor.

In this specification and the like, “normally off” means that a drain current per micrometer of channel width flowing through a transistor when no potential is applied to a gate or the gate is supplied with a ground potential is 1×10⁻²⁰ A or lower at room temperature, 1×10⁻¹⁸ A or lower at 85° C., or 1×10⁻⁶ A or lower at 125° C.

### Embodiment 1

An example of a semiconductor device including a transistor 200 of one embodiment of the present invention will be described in this embodiment.

### <Structure Example of Semiconductor Device>

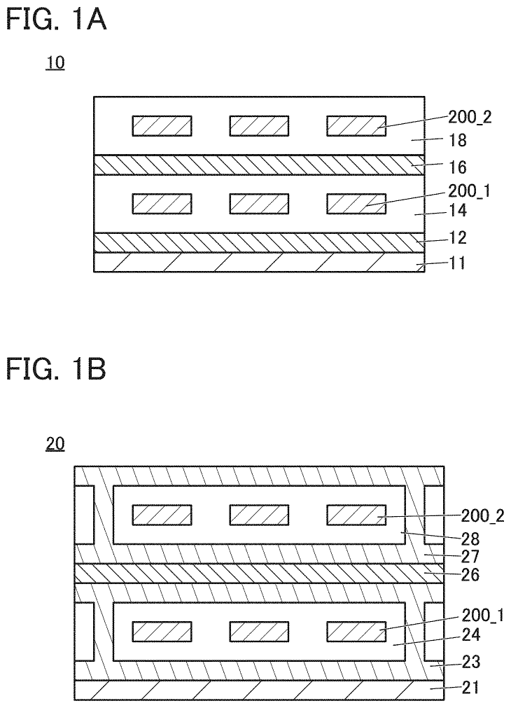

FIG. 1 is cross-sectional views of a semiconductor device including the transistor 200 of one embodiment of the present invention. Note that for clarity of the drawing, some components of the semiconductor device are not shown in FIG. 1.

As illustrated in FIG. 1A, a semiconductor device 10 of one embodiment of the present invention includes a substrate 11, an adjustment layer 12 over the substrate, a layer 14 including a transistor, an adjustment layer 16, and a layer 18 including a transistor, and the layers form a stacked-layer structure. In addition, at least one or more transistors 200_1 are provided in the layer 14 including the transistor, and at least one or more transistors 200_2 are provided in the layer 18 including the transistor.

Note that the transistor 200_1 and the transistor 200_2 may have either different structures or the same structures. In the specification below, the transistor 200_1 and the transistor 200_2 are collectively described as the transistor 200 in some cases.

The transistor 200 preferably uses a metal oxide functioning as an oxide semiconductor (hereinafter also referred to as an oxide semiconductor) in a semiconductor including a region where a channel is formed (hereinafter also referred to as a channel formation region).

As the oxide semiconductor, for example, a metal oxide such as an In—M—Zn oxide (the element M is one or more of aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used. As the oxide semiconductor, an In—Ga—Zn oxide, an In—Ga oxide, or an In—Zn oxide may be used.

The transistor 200 using an oxide semiconductor in the channel formation region has an extremely low leakage current in a non-conduction state; hence, a semiconductor device with low power consumption can be provided.

Furthermore, by using an oxide semiconductor, a variety of elements can be stacked and three-dimensionally integrated. In other words, an oxide semiconductor can be deposited by a sputtering method or the like; therefore, a three-dimensional integrated circuit (a 3D integrated circuit) in which a circuit is developed not only on a flat surface of a substrate but also in a perpendicular direction can be obtained.

Meanwhile, higher accuracy is required for mask adjustment (alignment) in a light-exposure step with higher integration of the semiconductor device. Furthermore, a margin for alignment in design tends to decrease.

As the total number of films forming the stacked-layer structure is increased owing to higher integration, an internal stress generated from a thin film deposited over the substrate is also increased. By the action of the internal stress of the component parallel to the substrate, distortion may be caused in the substrate and the semiconductor device provided over the substrate, and a deviation of focus may occur in a light-exposure step to cause a focus blur. In the case where distortion is caused in the substrate, the substrate cannot be adsorbed, or if the substrate is absorbed, the substrate becomes in an unstable state when introduced into an apparatus. Furthermore, a deviation for alignment occurs in some cases.

Here, the internal stress includes stresses in two directions, i.e., a tensile stress and a compressive stress. For example, the tensile stress acts in an extending direction with respect to a film at the interface between the substrate and the thin film and acts in a shrinking direction with respect to the substrate. Accordingly, in the case where the substrate is thin and does not have sufficiently high mechanical strength, the substrate is deformed, so that a formation surface of the substrate becomes a concave surface. In contrast, when the substrate is thick or has sufficiently high mechanical strength and the thin film cannot withstand the tensile stress, a crack is generated on the film surface in some times.

The compressive stress acts in a compressing direction with respect to the film at the interface between the substrate and the thin film and acts in an extending direction with respect to the substrate. Accordingly, in the case where the substrate is thin and does not have sufficiently high mechanical strength, the substrate is deformed, so that the formation surface of the substrate becomes a convex surface. In contrast, when the substrate is thick or has sufficiently high mechanical strength and the thin film cannot withstand the tensile stress, the film may leave from the substrate surface to be separated from the substrate surface with a crack generated over the entire surface, and the separated films may overlap with each other.

Therefore, in increasing the integration degree, a deviation of alignment is likely to occur owing to distortion of the substrate, while precision is required for alignment in design.

In particular, in the case where the semiconductor device has repeating stacked-layer structures, the internal stresses of the layer structures of the repeating units, that is, the total of the internal stresses of all the films forming the layer structures of the repeating units (also referred to as the total internal stress) act in the same direction. Therefore, as the number of layer structures of repeating units is increased, the total internal stress applied in one direction becomes larger.

Thus, in a stacked-layer structure of n (n is a natural number of 2 or more) repeating layer structures, an adjustment layer is preferably provided between the n-1-th layer structure and the n-th layer structure. The adjustment layer has an internal stress in a direction against the total internal stress of the layer structures of the repeating units. Specifically, in the case where the total internal stress acts in a compressing direction in the layer structures of the repeating units, the total internal stress of the adjustment layer preferably acts in a tensile direction.

Therefore, as shown in the semiconductor device 10 illustrated in FIG. 1A, the adjustment layer 16 is preferably provided between the layer 14 including the transistor and the layer 18 including the transistor.

Specifically, the total internal stress of the layer 14 including the transistor and the layer 18 including the transistor acts in the same direction. In contrast, the total internal stress of the adjustment layer 16 acts in the opposite direction of the total internal stress of the layer 14 including the transistor or the layer 18 including the transistor.

Here, it is sufficient that the direction of the total internal stress of the adjustment layer 16 be opposite to the direction of the total internal stress of the layer 14 including the transistor and the layer 18 including the transistor. In other words, in the case where the adjustment layer 16 has a stacked-layer structure, the internal stresses of all the layers included in the adjustment layer 16 do not necessarily act in the opposite direction of the internal stresses of the layer 14 including the transistor and the layer 18 including the transistor. The internal stress of the adjustment layer 16 regarded as one layer should act in the opposite direction of the internal stresses of the layer 14 including the transistor and the layer 18 including the transistor. Accordingly, a film functioning as a buffer may be included in the adjustment layer 16, as a film in contact with the layer including the transistor. The internal stress of the buffer film may act in the same direction as the layer 14 including the transistor and the layer 18 including the transistor.

The adjustment layer 16 can also serve as a wiring layer. Accordingly, the adjustment layer 16 may include a conductor. Specifically, the adjustment layer 16 may include a conductor that electrically connects the transistor 200_1 and the transistor 200_2. In addition, a wiring that is electrically connected to the transistor 200_1 or the transistor 200_2 may be routed.

Note that the adjustment layer 12 may be provided as needed and is not a required component. Although not illustrated, an adjustment layer may also be provided over the layer 18 including the transistor.

The above structure enables a reduction in the alignment margin and an increase in the design flexibility because the substrate is not distorted in the three-dimensional integrated circuit (the 3D integrated circuit) in which the circuit is developed also in the perpendicular direction.

### <Application Example of Semiconductor Device>

An example of the semiconductor device including the transistor 200 of one embodiment of the present invention will be described below with reference to FIG. 1B.

As illustrated in FIG. 1B, a semiconductor device 20 of one embodiment of the present invention includes a substrate 21, an insulator 23 having a barrier property, a layer 24 including a transistor, an adjustment layer 26, an insulator 27 having a barrier property, and a layer 28 including a transistor, and the layers form a stacked-layer structure. In addition, at least one or more transistors 200_1 are provided in the layer 24 including the transistor, and at least one or more transistors 200_2 are provided in the layer 28 including the transistor.

An oxide semiconductor that is easy to stack is used as a semiconductor including a region where a channel is formed in the transistor 200.

Meanwhile, it is highly probable that the electrical characteristics of the oxide semiconductor included in the transistor 200 vary owing to an impurity such as hydrogen, water, or a metal oxide; therefore, it is preferable to block the entry of an impurity from the outside.

Thus, the layer 24 including the transistor and the layer 28 including the transistor are preferably sealed with the use of the insulator 23 having a barrier property or the insulator 27 having a barrier property.

Note that in this specification, a function of inhibiting diffusion of impurities means a function of inhibiting diffusion of any one or all of the impurities. A film having a function of inhibiting diffusion of impurities may be referred to as a film through which impurities are less likely to pass, a film with low permeability of impurities, a film having a barrier property against impurities, or a barrier film against impurities, for example. A barrier film having conductivity is sometimes referred to as a conductive barrier film.

The insulator 23 having a barrier property is provided in contact with bottom, top, and side surfaces of the layer 24 including the transistor. The insulator 23 having a barrier property can be formed by a plurality of times of deposition of an insulator having a barrier property.

For example, the insulator 23 can be formed with at least three layers. Specifically, after a first insulating film having a barrier property is formed, the layer including the transistor is formed. A second insulating film having a barrier property is formed over the layer including the transistor. Subsequently, the layer including the transistor and the second insulating film having a barrier property are partly removed to expose the first insulating film having a barrier property. Then, a third film having a barrier property is formed so as to be in contact with the exposed surface of the first insulating film having a barrier property, the side surfaces of the layer including the transistor, and top and side surfaces of the second insulating film having a barrier property.

With the above structure, the transistor 200_1 can be sealed with the insulator 23 having a barrier property.

As the insulator having a barrier property, specifically, a metal oxide such as aluminum oxide or a nitride such as silicon nitride may have a function of inhibiting diffusion of oxygen (hereinafter, referred to as a barrier property). Compared with silicon oxide, in particular, aluminum oxide and silicon nitride have a function of inhibiting diffusion of oxygen or impurities such as water and hydrogen.

Therefore, for example, silicon nitride can be used as the insulator 23 having a barrier property or the insulator 27 having a barrier property. Moreover, it is possible to use, for example, a metal oxide such as aluminum oxide, hafnium oxide, magnesium oxide, gallium oxide, germanium oxide, yttrium oxide, zirconium oxide, lanthanum oxide, neodymium oxide, or tantalum oxide, or a nitride such as silicon nitride oxide.

The above-described film having a barrier property generally tends to have a high internal stress.

Accordingly, in the case where the total internal stress of the insulator 23 having a barrier property and the total internal stress of the layer 24 including the transistor act in the same direction, the adjustment layer 26 is provided, whereby distortion of the substrate 21 can be reduced. Therefore, the alignment margin can be reduced in a step of forming the stacked-layer structure of the insulator 23 having a barrier property and the layer 28 including the transistor over the adjustment layer 26.

In other words, a deviation of focus can be inhibited in a light-exposure step to reduce the occurrence of focus blur. In addition, the substrate can be adsorbed in a stable state when introduced into an apparatus. Furthermore, a deviation for alignment can be inhibited.

Furthermore, the design flexibility can be increased because the substrate is not distorted in the three-dimensional integrated circuit (the 3D integrated circuit) in which the circuit is developed also in the perpendicular direction. In the case where a stacked-layer structure of n or more layers is provided, film breakage or the like is less likely to occur even when an uppermost layer is provided; therefore, the semiconductor device can be manufactured with high yield.

The structure, method, and the like described in this embodiment can be used in an appropriate combination with the structures, the methods, and the like described in the other embodiments and examples.

### Embodiment 2

An example of a semiconductor device including the transistor 200 of one embodiment of the present invention will be described in this embodiment. The semiconductor device including the transistor of one embodiment of the present invention is a transistor including an oxide semiconductor in its channel formation region.

Here, an example of the semiconductor device including the transistor of one embodiment of the present invention will be described in detail below with reference to drawings.

### <Structure Example of Semiconductor Device>

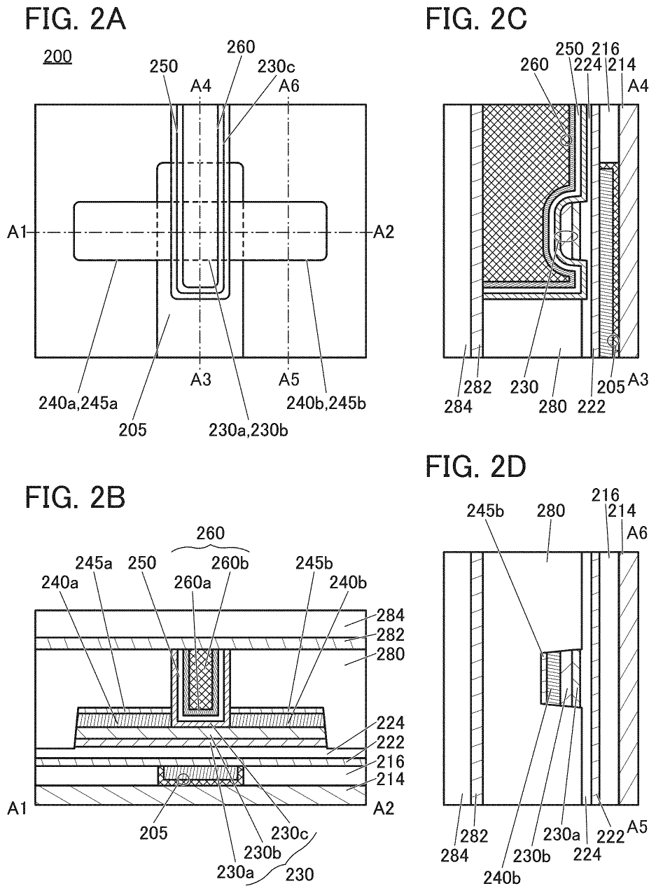

FIG. 2 illustrates a top view and cross-sectional views of a semiconductor device including the transistor 200 of one embodiment of the present invention. FIG. 2A is a top view of the semiconductor device. FIG. 2B and FIG. 2C are cross-sectional views of the semiconductor device. Here, FIG. 2B is a cross-sectional view of a portion indicated by the dashed-dotted line A1-A2 in FIG. 2A. FIG. 1C is a cross-sectional view of a portion indicated by dashed-dotted line A3-A4 in FIG. 1A. FIG. 2D is a cross-sectional view of a portion indicated by the dashed-dotted line A5-A6 in FIG. 2A. Note that for clarity of the drawing, some components are not illustrated in the top view of FIG. 2A.

The semiconductor device of one embodiment of the present invention includes the transistor 200, and an insulator 214, an insulator 216, an insulator 280, an insulator 282, and an insulator 284 that function as interlayer films. Note that the insulator 280 is provided to be in contact with at least an oxide 230.

### [Transistor 200]

As illustrated in FIG. 2, the transistor 200 is positioned over a substrate (not illustrated) and includes a conductor 205 that is positioned to be embedded in the insulator 216, an insulator 222 positioned over the insulator 216 and the conductor 205, an insulator 224 positioned over the insulator 222, the oxide 230 (an oxide 230a, an oxide 230b, and an oxide 230c) positioned over the insulator 224, an insulator 250 positioned over the oxide 230, a conductor 260 (a conductor 260a and a conductor 260b) positioned over the insulator 250, a conductor 240a and a conductor 240b in contact with part of the top surface of the oxide 230b, an insulator 245a over the conductor 240a, and an insulator 245b over the conductor 240b.

In the transistor 200, a metal oxide functioning as an oxide semiconductor (hereinafter also referred to as an oxide semiconductor) is used as the oxide 230 (the oxide 230a, the oxide 230b, and the oxide 230c), which includes a region where a channel is formed (hereinafter also referred to as a channel formation region).

Note that the oxide semiconductor functioning as the channel formation region preferably has a band gap of preferably 2 eV or higher, further preferably 2.5 eV or higher. With the use of an oxide semiconductor having such a wide band gap, the off-state current of the transistor can be reduced.

Note that the oxide 230 preferably has a stacked-layer structure of a plurality of oxide layers with different chemical compositions. Specifically, the atomic ratio of an element M to In in the metal oxide used as the oxide 230a is preferably higher than the atomic ratio of the element M to In in the metal oxide used as the oxide 230b.

A metal oxide that can be used as the oxide 230a or the oxide 230b can be used as the oxide 230c.

For example, an In—Ga—Zn oxide, a Ga—Zn oxide, gallium oxide, or the like may be used as the oxide 230a and the oxide 230c in the case where the oxide 230b is an In—Ga—Zn oxide.

The oxide 230b and the oxide 230c preferably have crystallinity. For example, a CAAC-OS (c-axis aligned crystalline oxide semiconductor) described later is preferably used. An oxide having crystallinity, such as a CAAC-OS, has a dense structure with small amounts of impurities and defects (e.g., oxygen vacancies) and high crystallinity. This can inhibit oxygen extraction from the oxide 230b by a source electrode or a drain electrode. This can reduce oxygen extraction from the oxide 230b even when heat treatment is performed; thus, the transistor 200 is stable with respect to high temperatures in a manufacturing process (what is called thermal budget).

Although a structure in which the oxide 230 has a three-layer stacked structure of the oxide 230a, the oxide 230b, and the oxide 230c in the transistor 200 is described, the present invention is not limited thereto. For example, the oxide 230 may be a single layer of the oxide 230 b or has a two-layer structure of the oxide 230a and the oxide 230b, a two-layer structure of the oxide 230b and the oxide 230c, or a stacked-layer structure including four or more layers. Alternatively, each of the oxide 230a, the oxide 230b, and the oxide 230c may have a stacked-layer structure.

As illustrated in FIG. 2D, it is preferable that at least a side surface of the oxide 230b and a side surface of the conductor 240 (the conductor 240a and the conductor 240b) be substantially perpendicular to the surface where the insulator 224 and the oxide 230a are in contact with each other. Specifically, in FIG. 2D, the side surface of the oxide 230b and the side surface of the conductor 240 preferably form an angle greater than or equal to 60° and less than or equal to 95°, further preferably greater than or equal to 88° and less than or equal to 92°, with respect to the surface where the insulator 224 and the oxide 230a are in contact with each other.

As illustrated in FIG. 2C, an upper end portion of the oxide 230 in the channel formation region preferably has a shape with curvature. That is, in the channel formation region, the top surface and the side surface of the oxide 230 are preferably smoothly connected with a curved surface without a corner. Since there is no corner in the channel formation region, electric field concentration due to one or both of electric fields of the conductor 260 functioning as a first gate electrode and the conductor 205 functioning as a second gate electrode does not occur, so that deterioration of the oxide 230 can be inhibited.

On the other hand, as illustrated in FIG. 2D, the upper end portions of the oxide 230 in a region overlapping with the conductor 240 preferably have a smaller curvature than the upper end portions of the oxide 230 in the channel formation region. The above structure can be formed by processing the oxide 230b and the conductor 240 with the same mask. Accordingly, the conductor 240 overlaps with the projected area of the oxide 230b, so that a minute transistor can be formed.

The conductor 260 functions as the first gate (also referred to as a top gate) electrode.

Here, the conductor 260 is embedded in an opening formed in the insulator 280 and the like in the transistor 200. In the step of forming the opening, part of a conductive layer to be the conductor 240 is exposed at a bottom portion of the opening provided in the insulator 280. In the conductive layer to be the conductor 240, a region overlapping with the bottom portion of the opening provided in the insulator 280 is removed, so that the conductor 240a and the conductor 240b are formed.

Thus, an end portion of the conductor 240a and an end portion of the conductor 240b are on the same plane as the side surfaces of the opening portion. The conductor 260 is embedded in the opening provided in the insulator 280 with the insulator 250 and the like therebetween, whereby the conductor 260 can be arranged in a region between the conductor 240a and the conductor 240b in a self-aligned manner without positional alignment.

Moreover, as shown in FIG. 2B or FIG. 2C, the top surface of the conductor 260 is substantially aligned with the top surface of the insulator 250 and the top surface of the oxide 230c.

In a region where the conductor 260 does not overlap with the oxide 230, the shortest distance from the surface where the conductor 260 is in contact with the insulator 250 to the top surface of the insulator 222 is preferably shorter than the shortest distance from the surface where the oxide 230b is in contact with the oxide 230a to the top surface of the insulator 222, as illustrated in FIG. 2C. That is, in the channel width direction of the transistor 200, the side surface of the oxide 230b is covered with the conductor 260 with at least the insulator 250 therebetween.

When the conductor 260 functioning as the gate electrode covers the side and top surfaces of the channel formation region of the oxide 230b with the insulator 250 and the like therebetween, the electric field of the conductor 260 affects the entire channel formation region of the oxide 230b. Thus, the on-state current of the transistor 200 can be increased and the frequency characteristics can be improved.

Note that the conductor 260 preferably includes the conductor 260a and the conductor 260b positioned over the conductor 260a. For example, the conductor 260a is preferably positioned to cover the bottom surface and the side surface of the conductor 260b.

For the conductor 260a, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, it is possible to inhibit a reduction in conductivity of the conductor 260b due to oxidation caused by oxygen contained in the insulator 250. As a conductive material having a function of inhibiting diffusion of oxygen, for example, tantalum, tantalum nitride, ruthenium, or ruthenium oxide is preferably used.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

Although the conductor 260 has a two-layer structure of the conductor 260a and the conductor 260b in FIG. 2, the conductor 260 may have a single-layer structure or a stacked-layer structure of three or more layers.

The conductor 205 sometimes functions as the second gate (also referred to as bottom gate) electrode.

When the conductor 205 functions as a gate electrode, by changing a potential applied to the conductor 205 not in conjunction with but independently of a potential applied to the conductor 260, the threshold voltage (Vth) of the transistor 200 can be adjusted. In particular, Vth of the transistor 200 can be higher in the case where a negative potential is applied to the conductor 205, and the off-state current can be reduced. Thus, a drain current at the time when a potential applied to the conductor 260 is 0 V can be lower in the case where a negative potential is applied to the conductor 205 than in the case where the negative potential is not applied to the conductor 205.

The conductor 205 is positioned to overlap with the oxide 230 and the conductor 260. Furthermore, the conductor 205 is preferably provided to be embedded in the insulator 214 or the insulator 216.

Note that in the channel width direction, the conductor 205 is preferably provided larger than the channel formation region of the oxide 230. As illustrated in FIG. 2C, it is particularly preferable that the conductor 205 extend to intersect the channel width direction of the oxide 230.

That is, the conductor 205 and the conductor 260 preferably overlap with each other with the insulators therebetween on an outer side of the side surface of the oxide 230 in the channel width direction. With this structure, the channel formation region of the oxide 230 can be electrically surrounded by the electric field of the conductor 260 functioning as the first gate electrode and the electric field of the conductor 205 functioning as the second gate electrode.

Although the conductor 205 has a structure in which a first conductor and a second conductor are stacked in FIG. 2, the present invention is not limited thereto. For example, the conductor 205 may have a single-layer structure or a stacked-layer structure of three or more layers. In the case where a component has a stacked-layer structure, layers may be distinguished by ordinal numbers corresponding to the formation order.

Here, for the first conductor of the conductor 205, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When a conductive material having a function of inhibiting diffusion of oxygen is used for the first conductor of the conductor 205, a reduction in the conductivity of the second conductor of the conductor 205 due to oxidation can be inhibited. As a conductive material having a function of inhibiting diffusion of oxygen, for example, tantalum, tantalum nitride, ruthenium, or ruthenium oxide is preferably used. Accordingly, the first conductor of the conductor 205 is a single layer or stacked layers of the above conductive materials. For example, the first conductor of the conductor 205 may be a stack of tantalum, tantalum nitride, ruthenium, or ruthenium oxide and titanium or titanium nitride.

A conductive material containing tungsten, copper, or aluminum as its main component is preferably used for a second conductor of the conductor 205. Note that the second conductor of the conductor 205 is illustrated as a single layer but may have a stacked-layer structure, for example, a stacked of the above conductive material and titanium or titanium nitride.

Furthermore, as illustrated in FIG. 2C, the conductor 205 extends to function as a wiring as well. However, without limitation to this structure, a structure in which a conductor functioning as a wiring is provided below the conductor 205 may be employed. In addition, the conductor 205 does not necessarily have to be provided in each transistor. For example, the conductor 205 may be shared by a plurality of transistors.

The conductor 240 (the conductor 240a and the conductor 240b) functions as a source electrode or a drain electrode.

As the conductor 240, TaNₓO_{y} is preferably used, for example. Note that TaNₓO_{y} may contain aluminum. As another example, titanium nitride, a nitride containing titanium and aluminum, ruthenium oxide, an oxide containing strontium and ruthenium, or an oxide containing lanthanum and nickel may be used. These materials are preferable because they are a conductive material that is not easily oxidized or a material that maintains the conductivity even when absorbing oxygen.

Over the conductor 240, an insulator 245 functioning as a barrier layer is preferably provided.

The insulator 245 is preferably in contact with the top surface of the conductor 240 as illustrated in FIG. 2B. The structure can inhibit the conductor 240 from absorbing excess oxygen included in the insulator 280. Furthermore, by inhibiting oxidation of the conductor 240, an increase in the contact resistance between the transistor 200 and a wiring can be inhibited. Consequently, the transistor 200 can have favorable electrical characteristics and reliability.

The insulator 245 preferably has a function of inhibiting diffusion of oxygen. For example, the insulator 245 preferably has a function of inhibiting oxygen diffusion more than the insulator 280.

An insulator containing an oxide of one or both of aluminum and hafnium is preferably deposited as the insulator 245, for example. An insulator containing aluminum nitride may be used as the insulator 245, for example.

The insulator 250 functions as a first gate insulator.

The insulator 250 is preferably positioned in contact with the oxide 230c. For the insulator 250, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like can be used. In particular, silicon oxide and silicon oxynitride are preferable because they are thermally stable.

Note that microwave-excited plasma treatment may be performed under an oxygen-containing atmosphere after the insulator 250 is deposited. By performing microwave-excited plasma treatment, hydrogen, water, or an impurity in the insulator 250 can be removed. Furthermore, microwave-excited plasma treatment improves the film quality of the insulator 250, whereby diffusion of hydrogen, water, an impurity, or the like can be inhibited. Accordingly, hydrogen, water, or an impurity can be inhibited from diffusing into the oxide 230 through the insulator 250 in a later step such as deposition of a conductive film to be the conductor 260 or by a later treatment such as heat treatment.

In solid silicon oxide, for example, bond energy between a hydrogen atom and a silicon atom is 3.3 eV, bond energy between a carbon atom and a silicon atom is 3.4 eV, and bond energy between a nitrogen atom and a silicon atom is 3.5 eV. Thus, in order to remove a hydrogen atom bonded to a silicon atom, radicals or ions having an energy of at least greater than or equal to 3.3 eV are made to collide with a bond portion between the hydrogen atom and the silicon atom to cut the bond between the hydrogen atom and the silicon atom.

Note that the same applies to other impurities such as nitrogen and carbon; radicals or ions having energy at least greater than or equal to bond energy are made to collide with a bond portion between an impurity atom and a silicon atom to cut the bond between the impurity atom and the silicon atom.

Here, examples of radicals and ions generated by microwave-excited plasma include O(³P), which is an oxygen atom radical in the ground state, O(¹D), which is an oxygen atom radical in the first excited state, and O₂+, which is a monovalent cation of an oxygen molecule. The energy of O(³P) is 2.42 eV, and the energy of O(¹D) is 4.6 eV. Furthermore, the energy of O₂⁺having charges is not uniquely determined because it is accelerated by the potential distribution in plasma and a bias; however, at least only the internal energy is higher than the energy of O(¹D).

That is, radicals and ions such as O(¹D) and O₂⁺can cut the bond between each of hydrogen, nitrogen, and a carbon atom in the insulator 250 and a silicon atom to remove hydrogen, nitrogen, and carbon bonded to the silicon atom. Furthermore, the impurities such as hydrogen, nitrogen, and carbon can also be reduced by thermal energy and the like applied to a substrate in performing the microwave-excited plasma treatment.

On the other hand, O(³P) has low reactivity, and thus does not react in the insulator 250 and is diffused deeply in the film. Alternatively, O(³P) reaches the oxide 230 through the insulator 250, and is diffused into the oxide 230. When O(³P) diffused into the oxide 230 comes close to the oxygen vacancy hydrogen enters, hydrogen in the oxygen vacancy is released from the oxygen vacancy and O(³P) enters the oxygen vacancy instead; thus, the oxygen vacancy is filled. Accordingly, an electron serving as a carrier can be inhibited from being generated in the oxide 230.

The proportion of O(³P) in the total radicals and ion species increases when microwave-excited plasma treatment is performed under a high pressure condition. The proportion of O(³P) is preferably high for compensation of the oxygen vacancies in the oxide 230. Thus, the pressure during the microwave-excited plasma treatment is higher than or equal to 133 Pa, preferably higher than or equal to 200 Pa, further preferably higher than or equal to 400 Pa. Furthermore, the oxygen flow rate ratio (O₂/O₂+Ar) is lower than or equal to 50%, preferably higher than or equal to 10% and lower than or equal to 30%.

For the insulator 250, an oxide material that releases part of oxygen by heating is preferably used. An oxide film that releases oxygen by heating is an oxide film in which the amount of released oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in thermal desorption spectroscopy (TDS) analysis. Note that the temperature of the film surface in the TDS analysis is preferably within the range of 100° C. to 700° C., or 100° C. to 400° C.

When an insulator from which oxygen is released by heating is provided as the insulator 250 in contact with the top surface of the oxide 230c, oxygen can be effectively supplied to the channel formation region of the oxide 230b and oxygen vacancies in the channel formation region of the oxide 230b can be reduced. Thus, a transistor that has stable electrical characteristics with small variation in electrical characteristics and improved reliability can be provided. Furthermore, the concentration of impurities such as water and hydrogen in the insulator 250 is preferably reduced.

A metal oxide may be provided between the insulator 250 and the conductor 260. The metal oxide preferably inhibits diffusion of oxygen from the insulator 250 into the conductor 260. Providing the metal oxide that inhibits diffusion of oxygen inhibits diffusion of oxygen from the insulator 250 into the conductor 260. That is, a reduction in the amount of oxygen supplied to the oxide 230 can be inhibited. Moreover, oxidation of the conductor 260 due to oxygen in the insulator 250 can be inhibited.

Note that the metal oxide functions as part of the gate insulator in some cases. Therefore, when silicon oxide, silicon oxynitride, or the like is used for the insulator 250, a metal oxide that is a high-k material with a high dielectric constant is preferably used as the metal oxide. When the gate insulator has a stacked-layer structure of the insulator 250 and the metal oxide, the stacked-layer structure can be thermally stable and have a high dielectric constant. Thus, a gate potential that is applied during operation of the transistor can be reduced while the physical thickness of the gate insulator is maintained. In addition, the equivalent oxide thickness (EOT) of the insulator functioning as the gate insulator can be reduced.

Specifically, a metal oxide containing one kind or two or more kinds selected from hafnium, aluminum, gallium, yttrium, zirconium, tungsten, titanium, tantalum, nickel, germanium, magnesium, and the like can be used. In particular, an insulator containing an oxide of one or both of aluminum and hafnium is preferably used.

The metal oxide may have a function of part of the first gate electrode. For example, an oxide semiconductor that can be used for the oxide 230 can be used as the metal oxide. In that case, when the conductor 260 is deposited by a sputtering method, the metal oxide can have a reduced electric resistance value to be a conductor.

With the metal oxide, the on-state current of the transistor 200 can be increased without a reduction in the influence of the electric field from the conductor 260. Since a distance between the conductor 260 and the oxide 230 is kept by the physical thicknesses of the insulator 250 and the metal oxide, leakage current between the conductor 260 and the oxide 230 can be inhibited. Moreover, when the stacked-layer structure of the insulator 250 and the metal oxide is provided, the physical distance between the conductor 260 and the oxide 230 and the intensity of electric field applied to the oxide 230 from the conductor 260 can be easily adjusted as appropriate.

The insulator 222 and the insulator 224 function as a second gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of further inhibiting diffusion of one or both of hydrogen and oxygen as compared to the insulator 224.

For the insulator 222, an insulator containing an oxide of one or both of aluminum and hafnium, which is an insulating material, is preferably used. As the insulator, aluminum oxide, hafnium oxide, an oxide containing aluminum and hafnium (hafnium aluminate), or the like is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen inside the transistor 200 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. A stack of silicon oxide, silicon oxynitride, or silicon nitride over these insulators may be used for the insulator 222.

For example, a single layer or stacked layers of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) may be used for the insulator 222. As miniaturization and high integration of transistors progress, a problem such as leakage current may arise because of a thinner gate insulator. When a high-k material is used for an insulator functioning as the gate insulator, a gate potential at the time when the transistor operates can be reduced while the physical thickness of the gate insulator is maintained.

It is preferable that oxygen be released from the insulator 224 in contact with the oxide 230 by heating like the insulator 250. Silicon oxide, silicon oxynitride, or the like is used as appropriate for the insulator 224, for example. When an insulator containing oxygen is provided in contact with the oxide 230, oxygen vacancies in the oxide 230 can be reduced and the reliability of the transistor 200 can be improved.

Note that the insulator 222 and the insulator 224 may have a stacked-layer structure of two or more layers. In that case, without limitation to a stacked-layer structure formed of the same material, a stacked-layer structure formed of different materials may be employed.

The insulator 214, the insulator 216, the insulator 280, the insulator 282, and the insulator 284 function as interlayer films.

The insulator 214 preferably functions as an insulating barrier film that inhibits diffusion of impurities such as water and hydrogen from the substrate side into the transistor 200. Accordingly, for the insulator 214, it is preferable to use an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use an insulating material having a function of inhibiting diffusion of oxygen (e.g., at least one of an oxygen atom, an oxygen molecule, and the like).

For example, aluminum oxide, silicon nitride, or the like is preferably used for the insulator 214. Accordingly, impurities such as water and hydrogen can be inhibited from being diffused to the transistor 200 side from the substrate side through the insulator 214. Alternatively, oxygen contained in the insulator 224 and the like can be inhibited from being diffused to the substrate side through the insulator 214. Note that the insulator 214 may have a stacked-layer structure of two or more layers. In that case, without limitation to a stacked-layer structure formed of the same material, a stacked-layer structure formed of different materials may be employed. For example, a stack of aluminum oxide and silicon nitride may be employed.

Furthermore, silicon nitride deposited by a sputtering method is preferably used for the insulator 214, for example. Accordingly, the hydrogen concentration in the insulator 214 can be low, and impurities such as water and hydrogen can be further inhibited from being diffused to the transistor 200 side from the substrate side through the insulator 214.

The permittivity of the insulator 216 functioning as an interlayer film is preferably lower than the permittivity of the insulator 214. When a material with a low permittivity is used for an interlayer film, parasitic capacitance generated between wirings can be reduced. For the insulator 216, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate, for example.

The insulator 216 preferably includes a region that has a low hydrogen concentration and contains oxygen in excess of that in the stoichiometric composition (hereinafter also referred to as an excess-oxygen region), or preferably contains oxygen that is released by heating (hereinafter also referred to as excess oxygen). For example, silicon oxide deposited by a sputtering method is preferably used for the insulator 216. Thus, entry of hydrogen into the oxide 230 can be inhibited; alternatively, oxygen can be supplied to the oxide 230 to reduce oxygen vacancies in the oxide 230. Thus, a transistor that has stable electrical characteristics with small variation in electrical characteristics and improved reliability can be provided.

Note that the insulator 216 may have a stacked-layer structure. For example, in the insulator 216, an insulator similar to the insulator 214 may be provided at least in a portion in contact with a side surface of the conductor 205. With such a structure, oxidation of the conductor 205 due to oxygen contained in the insulator 216 can be inhibited. Alternatively, a reduction in the amount of oxygen contained in the insulator 216 due to the conductor 205 can be inhibited.

The insulator 280 is provided over the insulator 224, the oxide 230, and the conductor 240. In addition, the top surface of the insulator 280 may be planarized.

The insulator 280 functioning as an interlayer film preferably has a low permittivity. When a material with a low permittivity is used for an interlayer film, parasitic capacitance generated between wirings can be reduced. The insulator 280 is preferably provided using a material similar to that for the insulator 216, for example. In particular, silicon oxide and silicon oxynitride, which have thermal stability, are preferable. Materials such as silicon oxide, silicon oxynitride, and porous silicon oxide are particularly preferable because a region containing oxygen released by heating can be easily formed.

The concentration of impurities such as water and hydrogen in the insulator 280 is preferably reduced. Moreover, the insulator 280 preferably has a low hydrogen concentration and includes an excess-oxygen region or excess oxygen, and may be provided using a material similar to that for the insulator 216, for example. Note that the insulator 280 may have a stacked-layer structure of two or more layers.

Like the insulator 214 and the like, the insulator 282 preferably functions as an insulating barrier film that inhibits diffusion of impurities such as water and hydrogen into the insulator 280 from above. In addition, like the insulator 214 and the like, the insulator 282 preferably has a low hydrogen concentration and has a function of inhibiting diffusion of hydrogen.

As illustrated in FIG. 2B, the insulator 282 is preferably in contact with the top surface of each of the conductor 260, the insulator 250, and the oxide 230c. This can inhibit entry of impurities such as hydrogen contained in the insulator 284 and the like into the insulator 250. Thus, adverse effects on the electrical characteristics of the transistor and the reliability of the transistor can be inhibited.

The insulator 284 functioning as an interlayer film is preferably provided over the insulator 282. Like the insulator 216 or the like, the insulator 284 preferably has a low permittivity. As in the insulator 224 and the like, the concentration of impurities such as water and hydrogen in the insulator 284 is preferably reduced.

### <Constituent Materials of Semiconductor Device>

Constituent materials that can be used for the semiconductor device will be described below.

### <<Substrate>>

As a substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon, germanium, or the like as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor element, a resistor, a switching element, a light-emitting element, and a memory element.

### <<Insulator>>

Examples of the insulator include an oxide, a nitride, an oxynitride, a nitride oxide, a metal oxide, a metal oxynitride, and a metal nitride oxide, each of which has an insulating property.

As miniaturization and high integration of transistors progress, for example, a problem such as a leakage current may arise because of a thinner gate insulator. When a high-k material is used for the insulator functioning as a gate insulator, the voltage during the operation of the transistor can be lowered while the physical thickness of the gate insulator is maintained. In contrast, when a material with a low relative permittivity is used for the insulator functioning as an interlayer film, parasitic capacitance generated between wirings can be reduced. Thus, a material is preferably selected depending on the function of an insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor using an oxide semiconductor is surrounded by insulators having a function of inhibiting passage of oxygen and impurities such as hydrogen (e.g., the insulator 214, the insulator 222, the insulator 245, the insulator 282, and the like), the electrical characteristics of the transistor can be stable. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen released by heating. For example, when a structure is employed in which silicon oxide or silicon oxynitride including a region containing oxygen released by heating is in contact with the oxide 230, oxygen vacancies included in the oxide 230 can be filled.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten nitride, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

For the conductor functioning as the gate electrode, it is particularly preferable to use a conductive material containing oxygen and a metal element contained in the metal oxide where the channel is formed. Alternatively, a conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

As the oxide 230, a metal oxide functioning as an oxide semiconductor is preferably used. A metal oxide that can be used as the oxide 230 of the present invention will be described below.

The metal oxide preferably contains at least indium or zinc. In particular, indium and zinc are preferably contained. In addition, gallium, yttrium, tin, or the like is preferably contained. Furthermore, one or more kinds selected from boron, titanium, iron, nickel, germanium, zirconium, molybdenum, lanthanum, cerium, neodymium, hafnium, tantalum, tungsten, magnesium, and the like may be contained.

Here, the case where the metal oxide is an In—M—Zn oxide containing indium, the element M, and zinc is considered. The element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, and magnesium. Note that two or more of the above elements may be used in combination as the element M.

Note that in this specification and the like, a metal oxide containing nitrogen is also collectively referred to as a metal oxide in some cases. A metal oxide containing nitrogen may be referred to as a metal oxynitride.

[Structure of metal oxide]

Oxide semiconductors (metal oxides) are classified into a single crystal oxide semiconductor and a non-single-crystal oxide semiconductor. Oxide semiconductors (metal oxides) can be classified into a single crystal oxide semiconductor and a non-single-crystal oxide semiconductor. Examples of a non-single-crystal oxide semiconductor include a CAAC-OS, a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. A pentagonal lattice arrangement, a heptagonal lattice arrangement, and the like are included in the distortion in some cases. Note that it is difficult to observe a clear crystal grain boundary (also referred to as grain boundary) even in the vicinity of distortion in the CAAC-OS. That is, formation of a crystal grain boundary is found to be inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like.

The CAAC-OS tends to have a layered crystal structure (also referred to as a stacked-layer structure) in which a layer containing indium and oxygen (hereinafter, an In layer) and a layer containing the element M, zinc, and oxygen (hereinafter, an (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is a metal oxide with high crystallinity. On the other hand, a clear crystal grain boundary is difficult to observe in the CAAC-OS; thus, it can be said that a reduction in electron mobility due to the crystal grain boundary is unlikely to occur. Entry of impurities, formation of defects, or the like might decrease the crystallinity of a metal oxide. This means that the CAAC-OS is a metal oxide having small amounts of impurities and defects (e.g., oxygen vacancies). Thus, a metal oxide including a CAAC-OS is physically stable. Therefore, the metal oxide including a CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

Note that an In—Ga—Zn oxide (hereinafter, IGZO) that is a kind of metal oxide containing indium, gallium, and zinc has a stable structure in some cases by being formed of the above-described nanocrystals. In particular, crystals of IGZO tend not to grow in the air and thus, a stable structure might be obtained when IGZO is formed of smaller crystals (e.g., the above-described nanocrystals) rather than larger crystals (here, crystals with a size of several millimeters or several centimeters).

An a-like OS is a metal oxide having a structure between those of the nc-OS and an amorphous oxide semiconductor. The a-like OS includes a void or a low-density region. That is, the a-like OS has low crystallinity as compared with the nc-OS and the CAAC-OS.

An oxide semiconductor (metal oxide) can have various structures that show different properties. Two or more of the amorphous oxide semiconductor, the polycrystalline oxide semiconductor, the a-like OS, the nc-OS, and the CAAC-OS may be included in an oxide semiconductor of one embodiment of the present invention.

### [Impurities]

Here, the influence of impurities in the metal oxide is described.

Entry of impurities into the oxide semiconductor forms defect states or oxygen vacancies in some cases. Thus, when impurities enter a channel formation region of the oxide semiconductor, the electrical characteristics of a transistor using the oxide semiconductor are likely to vary and its reliability is degraded in some cases. Moreover, if the channel formation region includes oxygen vacancies, the transistor tends to have normally-on characteristics.

The above-described defect states may include a trap state. Charge trapped by a trap state in the metal oxide takes a long time to disappear and may behave like fixed charge. Thus, a transistor including the metal oxide having a high density of trap states in the channel formation region has unstable electrical characteristics in some cases.

If impurities exist in the channel formation region of the oxide semiconductor, the crystallinity of the channel formation region may decrease, and the crystallinity of an oxide in contact with the channel formation region may decrease. Low crystallinity of the channel formation region tends to result in deterioration in stability or reliability of the transistor. Moreover, if the crystallinity of the oxide in contact with the channel formation region is low, an interface state may be formed and the stability or reliability of the transistor may deteriorate.

Therefore, the reduction in concentration of impurities in and around the channel formation region of the oxide semiconductor is effective in improving the stability or reliability of the transistor. Examples of impurities include hydrogen, nitrogen, an alkali metal, an alkaline earth metal, iron, nickel, and silicon.

Specifically, the concentration of the above impurities obtained by SIMS is lower than or equal to 1×10¹⁸ atoms/cm³, preferably lower than or equal to 2×10¹⁶ atoms/cm³ in and around the channel formation region of the oxide semiconductor. Alternatively, the concentration of the above impurities obtained by element analysis using EDX is lower than or equal to 1.0 atomic % in and around the channel formation region of the oxide semiconductor. When an oxide containing the element M is used as the oxide semiconductor, the concentration ratio of the impurities to the element M is lower than 0.10, preferably lower than 0.05 in and around the channel formation region of the oxide semiconductor. Here, the concentration of the element M used in the calculation of the concentration ratio may be a concentration in a region that is the same as the region whose concertation of the impurities is calculated or may be a concentration in the oxide semiconductor.

A metal oxide with a low impurity concentration has a low density of defect states and thus has a low density of trap states in some cases.

### <<Method for Manufacturing Semiconductor Device>>

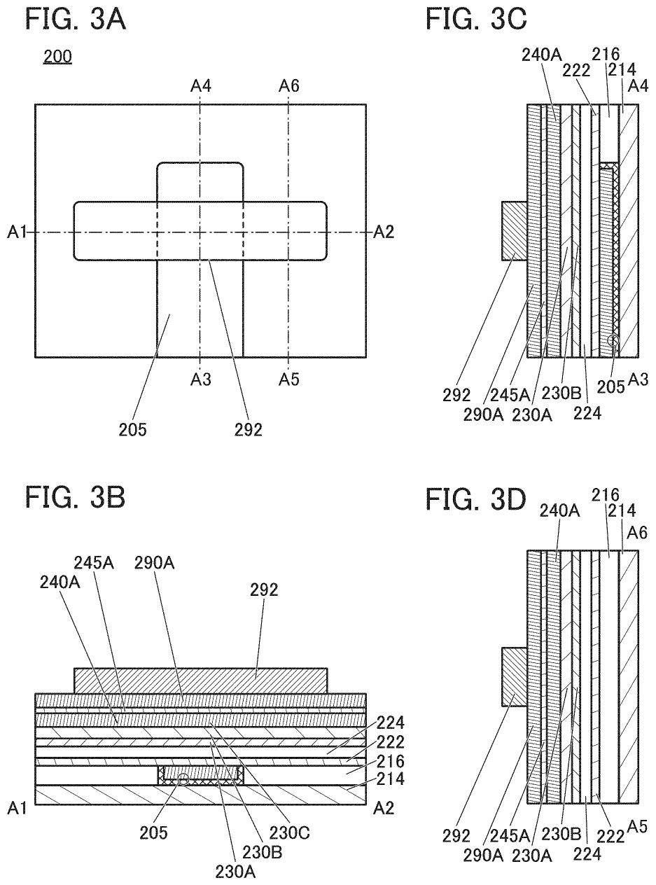

Next, a method for manufacturing a semiconductor device including the transistor 200 of one embodiment of the present invention, which is illustrated in FIG. 2, will be described with reference to FIG. 3 to FIG. 9.

In FIG. 3 to FIG. 9, A of each drawing is a top view. Moreover, B of each drawing is a cross-sectional view corresponding to a portion indicated by dashed-dotted line A1-A2 in A, and is also a cross-sectional view of the transistor 200 in the channel length direction. Furthermore, C of each drawing is a cross-sectional view corresponding to a portion indicated by dashed-dotted line A3-A4 in A, and is also a cross-sectional view of the transistor 200 in the channel width direction. Moreover, D of each drawing is a cross-sectional view corresponding to a portion indicated by dashed-dotted line A5-A6 in A in the drawing, and is also a cross-sectional view of the transistor 200 in the channel width direction. Note that for simplification of the drawing, some components are not shown in the top view of A of each drawing.

First, a substrate (not illustrated) is prepared, and the insulator 214 is deposited over the substrate. The insulator 214 can be deposited by a sputtering method, a chemical vapor deposition (CVD) method, a molecular beam epitaxy (MBE) method, a pulsed laser deposition (PLD) method, an ALD method, or the like.

Note that the CVD method can be classified into a plasma enhanced CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

Using a plasma CVD method, a high-quality film can be obtained at a relatively low temperature. A thermal CVD method is a deposition method that does not use plasma and thus enables less plasma damage to a processed object. For example, a wiring, an electrode, an element (a transistor, a capacitor element, or the like), or the like included in a semiconductor device might be charged up by receiving charge from plasma. In that case, accumulated charge might break the wiring, the electrode, the element, or the like included in the semiconductor device. In contrast, such plasma damage does not occur in the case of a thermal CVD method, which does not use plasma, and thus the yield of the semiconductor device can be increased. In addition, a thermal CVD method does not cause plasma damage during deposition, so that a film with few defects can be obtained.

An ALD method, which enables one atomic layer to be deposited at a time using self-regulating characteristics of atoms, has advantages such as deposition of an extremely thin film, deposition on a component with a high aspect ratio, deposition of a film with a small number of defects such as pinholes, deposition with excellent coverage, and low-temperature deposition. Furthermore, the ALD method includes a PEALD (plasma enhanced ALD) method using plasma. The use of plasma is sometimes preferable because deposition at a lower temperature is possible. Note that a precursor used in an ALD method sometimes contains impurities such as carbon. Thus, in some cases, a film provided by an ALD method contains impurities such as carbon in a larger amount than a film provided by another deposition method. Note that impurities can be quantified by X-ray photoelectron spectroscopy (XPS).

Unlike a deposition method in which particles ejected from a target or the like are deposited, a CVD method and an ALD method are deposition methods in which a film is formed by reaction at a surface of a processed object. Thus, a CVD method and an ALD method are deposition methods that enable favorable step coverage almost regardless of the shape of a processed object. In particular, an ALD method has excellent step coverage and excellent thickness uniformity and thus is suitable for covering a surface of an opening portion with a high aspect ratio, for example. On the other hand, an ALD method has a relatively low deposition rate, and thus is preferably used in combination with another deposition method with a high deposition rate, such as a CVD method, in some cases.

A CVD method and an ALD method enable control of the composition of a film to be obtained with the use of the flow rate ratio of the source gases. For example, using a CVD method and an ALD method, a film with a certain composition can be formed depending on the flow rate ratio of the source gases. Moreover, for example, by a CVD method and an ALD method, a film whose composition is continuously changed can be formed by changing the flow rate ratio of the source gases during the deposition. In the case where the film is deposited while the flow rate ratio of the source gases is changed, as compared to the case where the film is deposited using a plurality of deposition chambers, the time taken for the deposition can be shortened because the time taken for transfer and pressure adjustment is omitted. Thus, the productivity of the semiconductor device can be increased in some cases.

In this embodiment, for the insulator 214, aluminum oxide is deposited by a sputtering method. In addition, the insulator 214 may have a multilayer structure.

Next, the insulator 216 is deposited over the insulator 214. The insulator 216 can be deposited by a sputtering method, a CVD method, an MBE method, a PLD method, an ALD method, or the like. In this embodiment, for the insulating film to be the insulator 216, silicon oxynitride is deposited by a CVD method.

Then, an opening reaching the insulator 214 is formed in the insulator 216. Examples of the opening include a groove and a slit. A region where an opening is formed is referred to as an opening portion in some cases. Wet etching can be used for the formation of the opening; however, dry etching is preferably used for microfabrication. As the insulator 214, it is preferable to select an insulator that functions as an etching stopper film used in forming the groove by etching the insulator 216. For example, in the case where silicon oxynitride is used for the insulator 216 in which the groove is to be formed, silicon nitride, aluminum oxide, or hafnium oxide is preferably used for the insulator 214.

As a dry etching apparatus, a capacitively coupled plasma (CCP) etching apparatus including parallel plate electrodes can be used. The capacitively coupled plasma etching apparatus including the parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

After the formation of the opening, a conductive film to be the first conductor of the conductor 205 is deposited. The conductive film preferably includes a conductor that has a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used. The conductive film can be formed by a sputtering method, a CVD method, an MBE method, a PLD method, an ALD method, or the like.

In this embodiment, as the conductive film to be the first conductor of the conductor 205, a tantalum nitride film or a film in which titanium nitride is stacked over tantalum nitride is deposited by a sputtering method. With the use of such a metal nitride for the first conductor of the conductor 205, even when a metal that easily diffuses, such as copper, is used for the second conductor of the conductor 205 described later, the metal can be prevented from diffusing outward through the first conductor of the conductor 205.

Next, a conductive film to be the second conductor of the conductor 205 is deposited over the conductive film to be the first conductor of the conductor 205. The conductive film can be deposited by a plating method, a sputtering method, a CVD method, an MBE method, a PLD method, an ALD method, or the like. In this embodiment, tungsten is deposited for the conductive film.

Next, CMP (Chemical Mechanical Polishing) treatment is performed to partly remove the conductive film to be the first conductor of the conductor 205 and the conductive film to be the second conductor of the conductor 205 to expose the insulator 216. As a result, the conductive film to be the first conductor of the conductor 205 and the conductive film to be the second conductor of the conductor 205 remain only in the opening portion. Thus, the conductor 205 including the first conductor of the conductor 205 and the second conductor of the conductor 205, which has a flat top surface, can be formed (see FIG. 3).

Note that after the conductor 205 is formed, a groove may be formed in the second conductor of the conductor 205 by removal of part of the second conductor of the conductor 205, a conductive film may be deposited over the conductor 205 and the insulator 216 so as to fill the groove, and then CMP treatment may be performed. By the CMP treatment, part of the conductive film is removed to expose the insulator 216. Note that part of the second conductor of the conductor 205 is preferably removed by a dry etching method or the like.

Through the above steps, the conductor 205 including the conductive film, which has a flat top surface, can be formed. The improvement in planarity of the top surfaces of the insulator 216 and the conductor 205 can improve crystallinity of the oxide 230a, the oxide 230b, and the oxide 230c. Note that the conductive film is preferably formed using a material similar to that for the first conductor of the conductor 205 or the second conductor of the conductor 205.

A method for forming the conductor 205 which is different from the above will be described below.

A conductive film to be the conductor 205 is deposited over the insulator 214. The conductive film to be the conductor 205 can be deposited by a sputtering method, a CVD method, an MBE method, a PLD method, an ALD method, or the like. The conductive film to be the conductor 205 can be a multilayer film. For example, tungsten is deposited as the conductive film to be the conductor 205.

Next, the conductive film to be the conductor 205 is processed by a lithography method, so that the conductor 205 is formed.

Note that in the lithography method, first, a resist is exposed to light through a mask. Next, a region exposed to light is removed or left using a developer, so that a resist mask is formed. Then, etching treatment through the resist mask is conducted, whereby the conductor, the semiconductor, the insulator, or the like can be processed into a desired shape. The resist mask is formed through, for example, exposure of the resist to KrF excimer laser light, ArF excimer laser light, EUV (Extreme Ultraviolet) light, or the like. Alternatively, a liquid immersion technique may be employed in which a gap between a substrate and a projection lens is filled with liquid (e.g., water) in light exposure. Alternatively, an electron beam or an ion beam may be used instead of the light. Note that a mask is unnecessary in the case of using an electron beam or an ion beam. Note that the resist mask can be removed by dry etching process such as ashing, wet etching process, wet etching process after dry etching process, or dry etching process after wet etching process.

In addition, a hard mask formed of an insulator or a conductor may be used instead of the resist mask. In the case where a hard mask is used, a hard mask with a desired shape can be formed by forming an insulating film or a conductive film that is the hard mask material over the conductive film to be the conductor 205, forming a resist mask thereover, and then etching the hard mask material. The etching of the conductive film to be the conductor 205 may be performed after removing the resist mask or with the resist mask remaining. In the latter case, the resist mask sometimes disappears during the etching. The hard mask may be removed by etching after the etching of the conductive film to be the conductor 205. Meanwhile, the hard mask is not necessarily removed when the hard mask material does not affect subsequent steps or can be utilized in subsequent steps.

Next, an insulating film to be the insulator 216 is formed over the insulator 214 and the conductor 205. The insulating film is formed to be in contact with the top surface and side surface of the conductor 205. The insulating film can be deposited by a sputtering method, a CVD method, an MBE method, a PLD method, an ALD method, or the like.

Here, the thickness of the insulating film to be the insulator 216 is preferably greater than or equal to the thickness of the conductor 205. For example, when the thickness of the conductor 205 is 1, the thickness of the insulating film to be the insulator 216 is greater than or equal to 1 and less than or equal to 3.

Next, CMP treatment is performed on the insulating film to be the insulator 216, so that part of the insulating film to be the insulator 216 is removed and a surface of the conductor 205 is exposed. Thus, the conductor 205 and the insulator 216 whose top surfaces are flat can be formed. The above is the different method for forming the conductor 205.

Next, the insulator 222 is deposited over the insulator 216 and the conductor 205. The insulator 222 can be deposited by a sputtering method, a CVD method, an MBE method, a PLD method, an ALD method, or the like. In this embodiment, hafnium oxide or aluminum oxide is deposited as the insulator 222 by an ALD method.

Sequentially, heat treatment is preferably performed. The heat treatment is performed at a temperature higher than or equal to 250° C. and lower than or equal to 650° C., preferably higher than or equal to 300° C. and lower than or equal to500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen.

In this embodiment, the heat treatment is performed in such a manner that treatment is performed at 400° C. in a nitrogen atmosphere for one hour after the deposition of the insulator 222, and then another treatment is successively performed at 400° C. in an oxygen atmosphere for one hour. By the heat treatment, impurities such as water and hydrogen contained in the insulator 222 can be removed, for example. The heat treatment can also be performed after the deposition of the insulator 224, for example.

Then, the insulator 224 is deposited over the insulator 222. The insulator 224 can be deposited by a sputtering method, a CVD method, an MBE method, a PLD method, an ALD method, or the like. In this embodiment, as the insulator 224, a silicon oxynitride film is deposited by a CVD method.

Here, plasma treatment containing oxygen may be performed under reduced pressure so that an excess-oxygen region can be formed in the insulator 224. For the plasma treatment containing oxygen, an apparatus including a power source for generating high-density plasma using a microwave is preferably used, for example. Alternatively, a power source for applying an RF (Radio Frequency) to the substrate side may be included. The use of high-density plasma enables high-density oxygen radicals to be generated, and RF application to the substrate side allows the oxygen radicals generated by the high-density plasma to be efficiently introduced into the insulator 224. Alternatively, after plasma treatment containing an inert gas is performed using this apparatus, plasma treatment containing oxygen may be performed to compensate for released oxygen. Note that impurities such as water and hydrogen contained in the insulator 224 can be removed by selecting the conditions for the plasma treatment appropriately. In that case, the heat treatment does not need to be performed.

Here, after aluminum oxide is deposited over the insulator 224 by a sputtering method, for example, CMP treatment may be performed until the insulator 224 is exposed. The CMP treatment can planarize and smooth the surface of the insulator 224. When the CMP treatment is performed on the aluminum oxide positioned over the insulator 224, it is easy to detect the endpoint of the CMP treatment. Although part of the insulator 224 is polished by the CMP treatment and the thickness of the insulator 224 is reduced in some cases, the thickness can be adjusted when the insulator 224 is deposited. Planarizing and smoothing the surface of the insulator 224 can prevent deterioration in the coverage with an oxide deposited later and a decrease in the yield of the semiconductor device in some cases. The deposition of aluminum oxide over the insulator 224 by a sputtering method is preferred because oxygen can be added to the insulator 224.

Next, an oxide film 230A and an oxide film 230B are deposited in this order over the insulator 224 (see FIG. 3). Note that it is preferable to deposit the oxide film 230A and the oxide film 230B successively without exposure to the air. By the deposition without exposure to the air, impurities or moisture from the atmospheric environment can be prevented from being attached onto the oxide film 230A and the oxide film 230B, so that the vicinity of the interface between the oxide film 230A and the oxide film 230B can be kept clean.

The oxide film 230A and the oxide film 230B can be deposited by a sputtering method, a CVD method, an MBE method, a PLD method, an ALD method, or the like.

For example, in the case where the oxide film 230A and the oxide film 230B are deposited by a sputtering method, oxygen or a mixed gas of oxygen and a rare gas is used as a sputtering gas. Increasing the proportion of oxygen contained in the sputtering gas can increase the amount of excess oxygen in the deposited oxide films. In the case where the oxide films are deposited by a sputtering method, the above In—M—Zn oxide target or the like can be used.

In particular, when the oxide film 230A is deposited, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the oxide film 230B is formed by a sputtering method and the proportion of oxygen contained in the sputtering gas for deposition is higher than 30% and lower than or equal to 100%, preferably higher than or equal to 70% and lower than or equal to 100%, an oxygen-excess oxide semiconductor is formed. In a transistor using an oxygen-excess oxide semiconductor for its channel formation region, relatively high reliability can be obtained. However, one embodiment of the present invention is not limited thereto. In the case where the oxide film 230B is formed by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor for its channel formation region, relatively high field-effect mobility can be obtained. Furthermore, when the deposition is performed while the substrate is being heated, the crystallinity of the oxide film can be improved.

In this embodiment, the oxide film 230A is deposited by a sputtering method using an In—Ga—Zn oxide target with In:Ga:Zn=1:3:4 [atomic ratio]. The oxide film 230B is deposited by a sputtering method using an In—Ga—Zn oxide target with In:Ga:Zn=4:2:4.1 [atomic ratio]. Note that each of the oxide films is preferably formed by appropriate selection of deposition conditions and the atomic ratio to have characteristics required for the oxide 230.

Note that the insulator 222, the insulator 224, the oxide film 230A, and the oxide film 230B are preferably deposited without exposure to the air. For example, a multi-chamber deposition apparatus is used.

Next, heat treatment may be performed. For the heat treatment, the above-described heat treatment conditions can be used. Through the heat treatment, impurities such as water and hydrogen in the oxide film 230A and the oxide film 230B can be removed, for example. In this embodiment, treatment is performed at 400° C. in a nitrogen atmosphere for one hour, and treatment is successively performed at 400° C. in an oxygen atmosphere for one hour.

Next, a conductive film 240A is deposited over the oxide film 230B. The conductive film 240A can be deposited by a sputtering method, a CVD method, an MBE method, a PLD method, an ALD method, or the like (see FIG. 3). Note that heat treatment may be performed before the deposition of the conductive film 240A. This heat treatment may be performed under reduced pressure, and the conductive film 240A may be successively formed without exposure to the air. The treatment can remove moisture and hydrogen adsorbed onto the surface of the oxide film 230B and the like, and further can reduce the moisture concentration and the hydrogen concentration of the oxide film 230A and the oxide film 230B. The heat treatment is preferably performed at a temperature higher than or equal to 100° C. and lower than or equal to 400° C. In this embodiment, the heat treatment is performed at 200° C.

Next, an insulating film 245A functioning as a barrier layer is formed (see FIG. 3).

As the insulating film 245A, an aluminum oxide is formed by an ALD method, for example. With use of an ALD method, a dense film with a smaller number of defects such as cracks and pinholes or with a uniform thickness can be formed.

Next, a film 290A to be a hard mask is formed over the insulating film 245A (see FIG. 3). As the film 290A to be a hard mask, tungsten or tantalum nitride is formed by a sputtering method, for example.

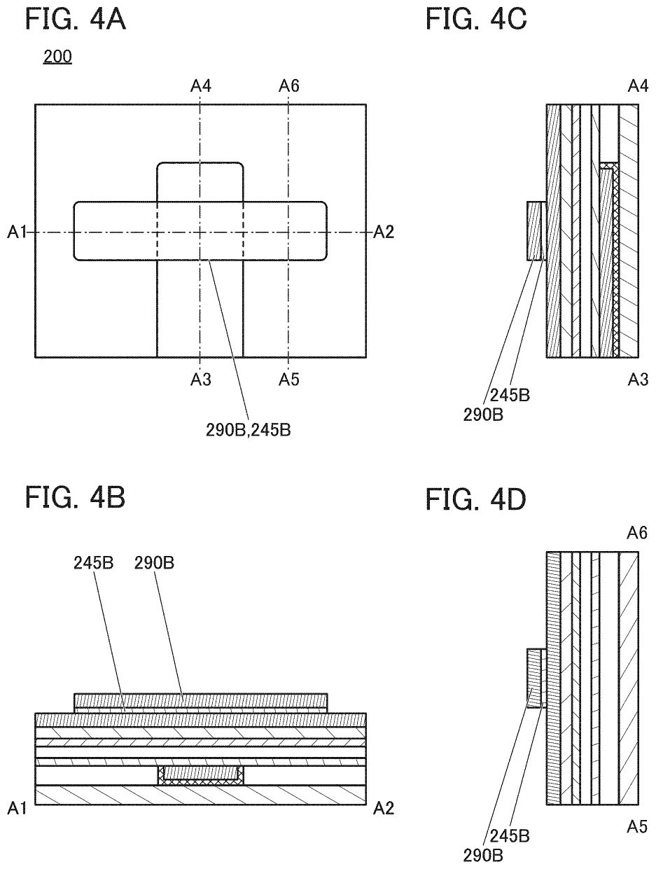

Next, a resist mask 292 is formed over the film 290A to be a hard mask by a photolithography method. Part of the film 290A to be a hard mask and part of the insulating film 245A are selectively removed using the resist mask 292 to form a hard mask 290B and an insulating layer 245B (FIG. 4).

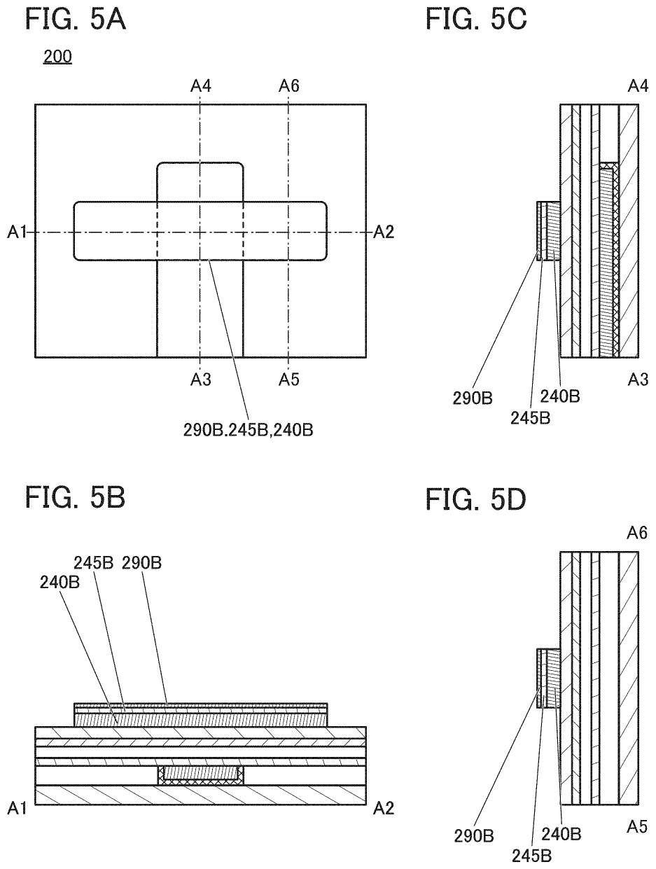

Next, part of the conductive film 240A is selectively removed using the hard mask 290B and the insulating layer 245B to form an island-shaped conductive layer 240B (FIG. 5). Note that part or all of the hard mask 290B may be removed at this time.

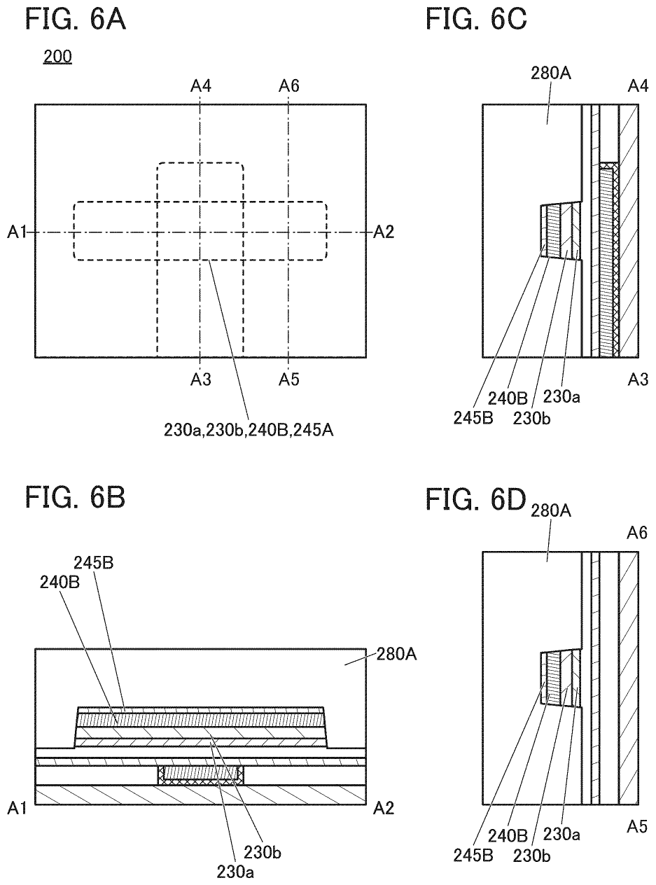

Subsequently, part of the oxide film 230A and part of the oxide film 230B are selectively removed using the island-shaped conductive layer 240B, the insulating layer 245B, and the hard mask 290B as a mask (FIG. 6). In this step, part of the insulator 224 is concurrently removed in some cases. After that, the hard mask 290B is removed, so that a stacked-layer structure of the island-shaped oxide 230a, the island-shaped oxide 230b, the island-shaped conductive layer 240B, and the island-shaped insulating layer 245B can be formed (FIG. 6).

Furthermore, the processing of the conductive film 240A using a hard mask 290 in this step can inhibit formation of etching that is unnecessary for the shape of the conductor 240 (also referred to as CD loss).

For example, in the case where a resist mask is used, the mask is side-etched in etching to expose the surface of an end portion of an object to be processed, and the corner is sometimes rounded. In the case where the defect is large in the conductor 240, the volume of the conductor 240 is sometimes decreased compared to the designed value, so that the on-state current becomes small in some cases.

Thus, with the use of the hard mask, when a material that has high selectivity of the etching rate to the hard mask is used as the object to be processed, the shape of the hard mask is maintained in etching and thus the defect in shape of the object to be processed can be inhibited. Specifically, the following material is preferably used as the mask: in the case where the etching rate of the material used for the hard mask is 1, the etching rate of the object to be processed is greater than or equal to 5, preferably greater than or equal to 10.

Next, an insulating film 280A is deposited over the stacked-layer structure of the island-shaped oxide 230a, the island-shaped oxide 230b, the island-shaped conductive layer 240B, and the island-shaped insulating layer 245B. The insulating film 280A can be deposited by a sputtering method, a CVD method, an MBE method, a PLD method, an ALD method, or the like. In this embodiment, as the insulating film 280A, a silicon oxide film is deposited by a CVD method or a sputtering method. Note that heat treatment may be performed before the insulating film 280A is deposited. The heat treatment may be performed under reduced pressure, and the insulating film may be successively deposited without exposure to the air. The treatment can remove moisture and hydrogen adsorbed onto the surface of the insulator 224 and the like, and further can reduce the moisture concentration and the hydrogen concentration of the oxide 230a, the oxide 230b, and the insulator 224. The conditions for the above-described heat treatment can be used.

The insulating film 280A may have a multilayer structure. The insulating film 280A may have a structure in which a silicon oxide film is deposited by a sputtering method and another silicon oxide film is deposited over the silicon oxide film by a CVD method, for example.

Next, the insulating film 280A is subjected to CMP treatment, so that the insulator 280 having a flat top surface is formed (see FIG. 6).

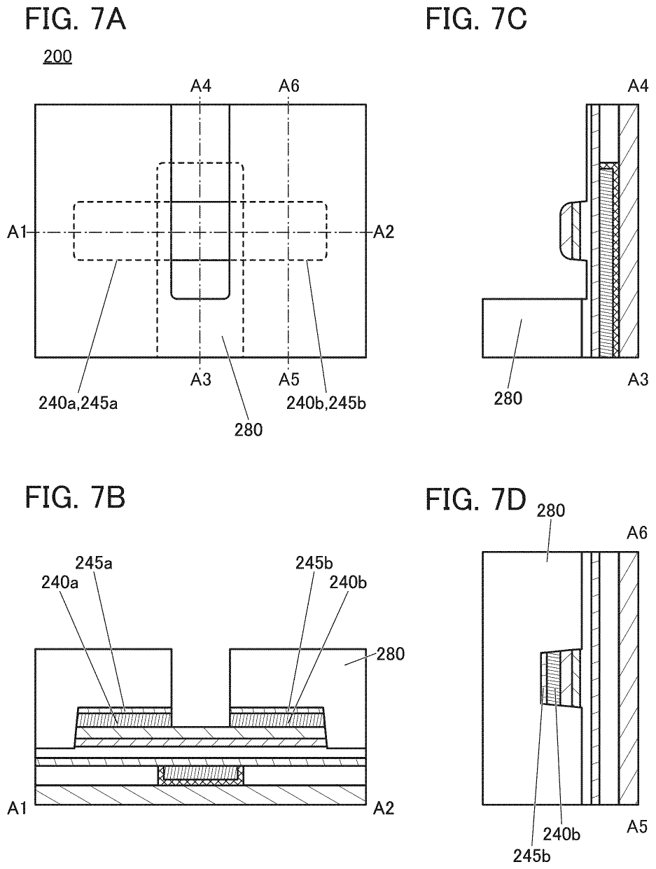

Then, part of the insulator 280 and part of the conductive layer 240B are processed to form an opening reaching the oxide 230b. The opening is preferably formed to overlap with the conductor 205. The conductor 240a, the conductive layer 240B, the insulator 245a, and the insulating layer 245B are formed by forming the opening. At this time, the thickness of the oxide 230b in a region overlapping with the opening may be reduced (see FIG. 7).

Part of the insulator 280, part of the insulating layer 245B, and part of the conductive layer 240B may be processed under different conditions. For example, part of the insulator 280 may be processed by a dry etching method, part of the insulating layer 245B may be processed by a wet etching method, and part of the conductive layer 240B may be processed by a dry etching method.

Here, it is preferable to remove impurities that are attached onto the surfaces of the oxide 230a, the oxide 230b, and the like or diffused into the oxide 230a, the oxide 230b, and the like. The impurities result from components contained in the insulator 280, the insulating layer 245B, and the conductive layer 240B; components contained in a member used in an apparatus used to form the opening; and components contained in a gas or a liquid used for etching, for instance. Examples of the impurities include aluminum, silicon, tantalum, fluorine, and chlorine.

In order to remove the above impurities and the like, cleaning treatment may be performed. Examples of the cleaning method include wet cleaning using a cleaning solution, plasma treatment using plasma, and cleaning by heat treatment, and any of these cleanings may be performed in appropriate combination.

As the wet cleaning, cleaning treatment may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

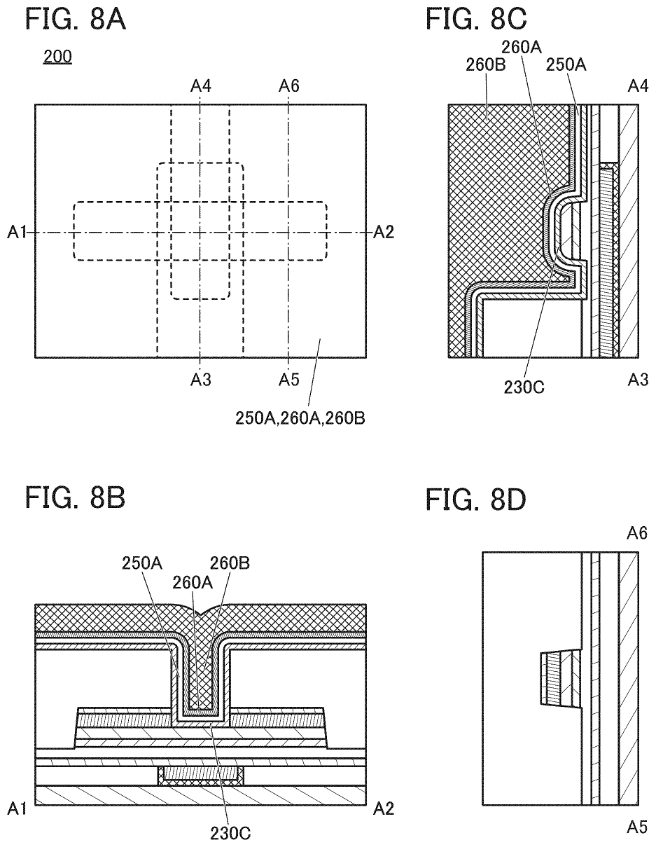

Next, heat treatment may be performed. The heat treatment is preferably performed in an oxygen-containing atmosphere. The heat treatment may be performed under reduced pressure, and an oxide film 230C may be successively deposited without exposure to the air (see FIG. 8). Such treatment can remove moisture and hydrogen adsorbed onto the surface of the oxide 230b or the like and can reduce the moisture concentration and the hydrogen concentration in the oxide 230a and the oxide 230b. The temperature of the heat treatment is preferably higher than or equal to 100° C. and lower than or equal to 400° C. In this embodiment, the heat treatment is performed at 200° C.

The oxide film 230C can be deposited by a sputtering method, a CVD method, an MBE method, a PLD method, an ALD method, or the like. The oxide film 230C is deposited by a deposition method similar to that for the oxide film 230A or the oxide film 230B in accordance with the characteristics required for the oxide film 230C. In this embodiment, the oxide film 230C is deposited by a sputtering method using an In—Ga—Zn oxide target with In:Ga:Zn=1:3:4 [atomic ratio] or 4:2:4.1 [atomic ratio]. Alternatively, the oxide film 230C is deposited by a sputtering method in such a manner that a film is deposited using an In—Ga—Zn oxide target having an atomic ratio of In: Ga:Zn=4:2:4.1 [atomic ratio] and another film is deposited thereover using an In—Ga—Zn oxide target having an atomic ratio of In:Ga:Zn=1:3:4 [atomic ratio].

In particular, in the deposition of the oxide film 230C, part of oxygen contained in the sputtering gas is sometimes supplied to the oxide 230a and the oxide 230b. Therefore, the proportion of oxygen contained in the sputtering gas for the oxide film 230C is higher than or equal to 70%, preferably higher than or equal to 80%, further preferably 100%.

Next, heat treatment may be performed. The heat treatment may be performed under reduced pressure, and an insulating film 250A may be successively deposited without exposure to the air. Such treatment can remove moisture and hydrogen adsorbed onto the surface of the oxide film 230C or the like and can reduce the moisture concentration and the hydrogen concentration in the oxide 230a, the oxide 230b, and the oxide film 230C. The temperature of the heat treatment is preferably higher than or equal to 100° C. and lower than or equal to 400° C.

The insulating film 250A can be deposited by a sputtering method, a CVD method, an MBE method, a PLD method, an ALD method, or the like (see FIG. 8). In this embodiment, as the insulating film 250A, silicon oxynitride is deposited by a CVD method. Note that the deposition temperature at the time of the deposition of the insulating film 250A is preferably higher than or equal to 350° C. to lower than 450° C., particularly preferably approximately 400° C. When the insulating film 250A is deposited at 400° C., an insulating film having few impurities can be deposited.

Next, a conductive film 260A and a conductive film 260B are deposited in this order. The conductive film 260A and the conductive film 260B can be deposited by a sputtering method, a CVD method, an MBE method, a PLD method, an ALD method, or the like. In this embodiment, the conductive film 260A is deposited by an ALD method, and the conductive film 260B is deposited by a CVD method (see FIG. 8).

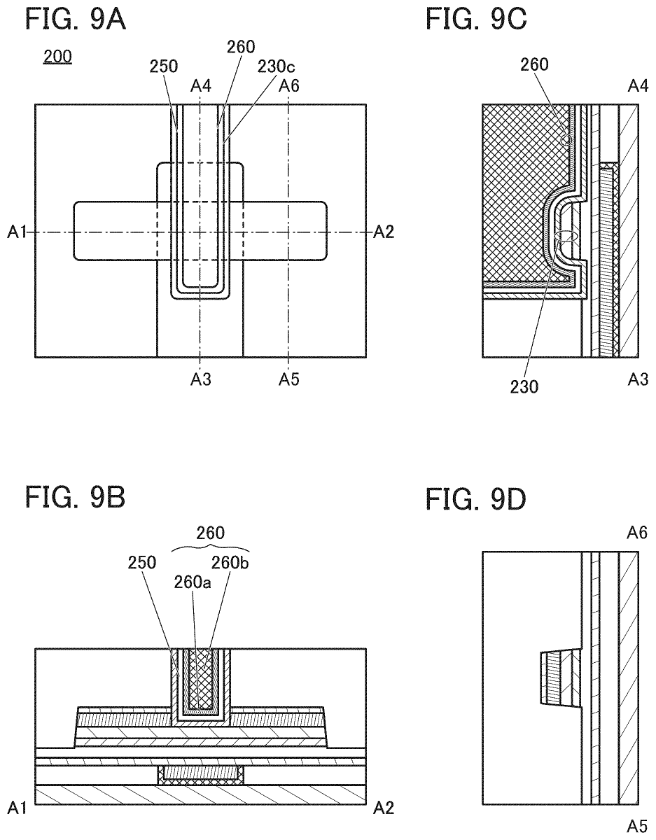

Subsequently, the oxide film 230C, the insulating film 250A, the conductive film 260A, and the conductive film 260B are polished by CMP treatment until the insulator 280 is exposed, whereby the oxide 230c, the insulator 250, and the conductor 260 (the conductor 260a and the conductor 260b) are formed (see FIG. 9). Accordingly, the oxide 230c is positioned to cover the inner wall (the side wall and bottom surface) of the opening reaching the oxide 230b. The insulator 250 is positioned to cover the inner wall of the opening with the oxide 230c therebetween. The conductor 260 is positioned to fill the opening with the oxide 230c and the insulator 250 therebetween.

Next, heat treatment may be performed. In this embodiment, the treatment is performed at 400° C. in a nitrogen atmosphere for one hour. The heat treatment can reduce the moisture concentration and the hydrogen concentration in the insulator 250 and the insulator 280.

Next, the insulator 282 is deposited over the oxide 230c, the insulator 250, the conductor 260, and the insulator 280. The insulator 282 can be deposited by a sputtering method, a CVD method, an MBE method, a PLD method, an ALD method, or the like. An aluminum oxide film or an silicon nitride film is preferably deposited as the insulator 282 by a sputtering method, for example. When an aluminum oxide film or a silicon nitride film is deposited by a sputtering method, diffusion of hydrogen contained in the insulator 284 into the oxide 230 can be inhibited. Forming the insulator 282 to be in contact with the conductor 260 is preferable, in which case oxidation of the conductor 260 can be inhibited.

When an aluminum oxide film is formed as the insulator 282 by a sputtering method, oxygen can be supplied to the insulator 280. Oxygen supplied to the insulator 280 is sometimes supplied to the channel formation region included in the oxide 230b through the oxide 230c. Furthermore, when oxygen is supplied to the insulator 280, oxygen that is contained in the insulator 280 before the formation of the insulator 282 might be supplied to the channel formation region included in the oxide 230b through the oxide 230c.

In addition, the insulator 282 may have a multilayer structure. For example, a structure may be employed in which an aluminum oxide film is deposited by a sputtering method and silicon nitride is deposited over the aluminum oxide film by a sputtering method.

Next, heat treatment may be performed. For the heat treatment, the above heat treatment conditions can be used. The heat treatment can reduce the moisture concentration and the hydrogen concentration of the insulator 280. Moreover, oxygen contained in the insulator 282 can be injected into the insulator 280.

Before the insulator 282 is deposited, the following steps may be performed: first, an aluminum oxide film is deposited over the insulator 280 and the like by a sputtering method, heat treatment is performed under the above heat treatment conditions, and then the aluminum oxide film is removed by CMP treatment. Through these steps, a larger number of excess-oxygen regions can be formed in the insulator 280. Note that in these steps, part of the insulator 280, part of the conductor 260, part of the insulator 250, and part of the oxide 230c are removed in some cases.

An insulator may be provided between the insulator 280 and the insulator 282. As the insulator, silicon oxide deposited by a sputtering method is used, for example. Providing the insulator can form an excess-oxygen region in the insulator 280.

Next, the insulator 284 may be deposited over the insulator 282. The insulator 284 can be deposited by a sputtering method, a CVD method, an MBE method, a PLD method, an ALD method, or the like (see FIG. 1).

Through the above process, the semiconductor device including the transistor 200 illustrated in FIG. 1 can be manufactured.

After the transistor 200 is formed, an opening may be formed to surround the transistor 200 and an insulator having a high barrier property against hydrogen or water may be formed to cover the opening. Surrounding the transistor 200 by the insulator having a high barrier property can prevent entry of moisture and hydrogen from the outside. Alternatively, a plurality of transistors 200 may be collectively surrounded by the insulator having a high barrier property against hydrogen or water. When an opening is formed to surround the transistor 200, for example, the formation of an opening reaching the insulator 214 or the insulator 222 and the formation of the insulator having a high barrier property in contact with the insulator 214 or the insulator 222 are suitable because these formation steps can also serve as part of the manufacturing steps of the transistor 200. The insulator having a high barrier property against hydrogen or water is formed using a material similar to that for the insulator 222, for example.

According to one embodiment of the present invention, a highly reliable semiconductor device can be provided. According to one embodiment of the present invention, a semiconductor device with favorable electrical characteristics can be provided. According to one embodiment of the present invention, a semiconductor device with a high on-state current can be provided. According to one embodiment of the present invention, a semiconductor device that can be miniaturized or highly integrated can be provided. According to one embodiment of the present invention, a semiconductor device with low power consumption can be provided.

### <Modification Example of Semiconductor Device>

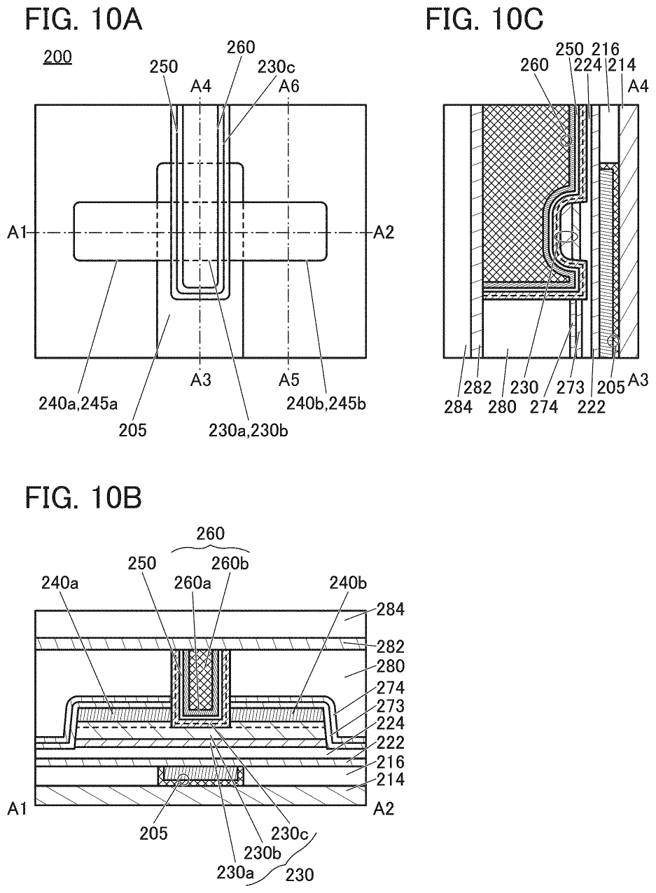

An example of a semiconductor device including the transistor 200 of one embodiment of the present invention is described below with reference to FIG. 10.

Here, FIG. 10A is a top view. FIG. 10B is a cross-sectional view corresponding to a portion indicated by dashed-dotted line A1-A2 in FIG. 10A. FIG. 10C is a cross-sectional view corresponding to a portion indicated by dashed-dotted line A3-A4 in FIG. 10A. For clarity of the drawing, some components are not illustrated in the top view of FIG. 10A.

The semiconductor device illustrated in FIG. 10 is different from the semiconductor device illustrated in FIG. 2 in that the oxide 230b has a stacked-layer structure. Additionally, it is different in that the oxide 230c has a stacked-layer structure. It is also different in that an insulator 273 and an insulator 274 are included.

The oxide 230c may have a stacked-layer structure of two or more layers. For example, in FIG. 10, the first oxide of the oxide 230c and the second oxide of the oxide 230c over the first oxide of the oxide 230c are included.

Specifically, the first oxide of the oxide 230c preferably contains at least one of the metal elements contained in the metal oxide used in the oxide 230b, and further preferably contains all of these metal elements. For example, it is preferable that an In—Ga—Zn oxide be used for the first oxide of the oxide 230c, and an In—Ga—Zn oxide, a Ga—Zn oxide, or gallium oxide be used for the second oxide of the oxide 230c. Owing to the structure, the density of defect states at the interface between the oxide 230b and the first oxide of the oxide 230c can be decreased.

The second oxide of the oxide 230c is preferably a metal oxide that inhibits diffusion or passage of oxygen, compared to the first oxide of the oxide 230c. Providing the second oxide of the oxide 230c between the insulator 250 and the first oxide of the oxide 230c can inhibit diffusion of oxygen contained in the insulator 280 into the insulator 250. Therefore, the oxygen is more likely to be supplied to the oxide 230b through the first oxide of the oxide 230c.

When the atomic ratio of In to the metal element of the main component in the metal oxide used for the second oxide of the oxide 230c is smaller than the atomic ratio of In to the metal element of the main component in the metal oxide used for the first oxide of the oxide 230c, the diffusion of In into the insulator 250 side can be inhibited. Since the insulator 250 functions as a gate insulator, the transistor exhibits poor characteristics when In enters the insulator 250 and the like. Thus, when the oxide 230c has a stacked-layer structure, a highly reliable semiconductor device can be provided.

The oxide 230b may have a stacked-layer structure of two or more layers. For example, in FIG. 10, the first oxide of the oxide 230b and the second oxide of the oxide 230b over the first oxide of the oxide 230b are included.

Specifically, the second oxide of the oxide 230b is preferably provided between the first oxide of the oxide 230b and the conductor 240 (the conductor 240a and the conductor 240b) functioning as a source electrode and a drain electrode. In the structure, the second oxide of the oxide 230b preferably has a function of inhibiting passage of oxygen.

It is preferable to place the second oxide of the oxide 230b having a function of inhibiting passage of oxygen between the first oxide of the oxide 230b and the conductor 240 which functions as the source electrode and the drain electrode, in which case the electrical resistance between the conductor 240 and the first oxide of the oxide 230b is reduced. Such a structure improves the electrical characteristics and reliability of the transistor 200.

The conductor 240 and the first oxide of the oxide 230b are not in contact with each other, which inhibits the conductor 240 from absorbing oxygen of the first oxide of the oxide 230b. Preventing oxidation of the conductor 240 can inhibit the decrease in conductivity of the conductor 240.

A metal oxide containing the element M may be used as the second oxide of the oxide 230b. In particular, aluminum, gallium, yttrium, or tin is preferably used as the element M The concentration of the element M in the second oxide of the oxide 230b is preferably higher than that of the first oxide of the oxide 230b. Alternatively, gallium oxide may be used as the second oxide of the oxide 230b. A metal oxide such as an In—M—Zn oxide may be used as the second oxide of the oxide 230b.

Specifically, the atomic ratio of the element M to In in the metal oxide used as the second oxide of the oxide 230b is preferably greater than the atomic ratio of the element M to In in the metal oxide used as the first oxide of the oxide 230b. The thickness of the second oxide of the oxide 230b is preferably greater than or equal to 0.5 nm and less than or equal to 5 nm, further preferably greater than or equal to 1 nm and less than or equal to 3 nm. The second oxide of the oxide 230b preferably has crystallinity. When the second oxide of the oxide 230b has crystallinity, release of oxygen in the first oxide of the oxide 230b can be reduced. When the second oxide of the oxide 230b has a crystal structure such as a hexagonal crystal structure, release of oxygen from the first oxide of the oxide 230b can be inhibited in some cases.

Contact between the conductor 240 (the conductor 240a and the conductor 240b) and the oxide 230 may make oxygen in the oxide 230 diffuse into the conductor 240, resulting in oxidation of the conductor 240. It is highly possible that oxidation of the conductor 240 lowers the conductivity of the conductor 240. Note that diffusion of oxygen in the oxide 230 into the conductor 240 can be rephrased as absorption of oxygen in the oxide 230 by the conductor 240.

Oxygen in the oxide 230 (typically in the oxide 230b) diffuses into the conductor 240, whereby another layer may be formed between the conductor 240 and the oxide 230. The layer contains more oxygen than the conductor 240 does, and thus the layer presumably has an insulating property. In this case, the three-layer structure of the conductor 240, the layer, and the oxide 230 can be regarded as a three-layer structure formed of metal-insulator-semiconductor, which is referred to as an MIS (Metal-Insulator-Semiconductor) structure or a diode junction structure having an MIS structure as its main part in some cases.

The insulator 273 having a barrier property may be provided to cover the top surface of the conductor 240 and the side surfaces of the oxide 230a, the oxide 230b, and the conductor 240. Note that when the insulator 273 is provided, the insulator 245 is not necessarily provided.

For example, oxygen vacancies are formed in the region of the oxide 230 which overlaps with the conductor 240 by the introduction of the metal element of the conductor 240 or absorption of oxygen by the conductor 240. That is, the vicinity of the surface of the oxide 230 which is in contact with the conductor 240 can locally have a lower resistance. The region of the oxide 230 which overlaps with the conductor 240 becomes low resistant; this can increase the on-state current of the transistor 200.

By contrast, the excess oxygen included in the insulator 280 is diffused through the side surface of the region of the oxide 230 which overlaps with the conductor 240 to the oxide 230; thus, the local lower-resistance region which is formed in the region of the oxide 230 which overlaps with the conductor 240 can be reduced and the on-state current of the transistor 200 can be lowered.

When the insulator 273 is provided, the excess oxygen included in the insulator 280 can be inhibited from being supplied through the side surface of the region of the oxide 230 which overlaps with the conductor 240. On the other hand, the excess oxygen included in the insulator 280 can be supplied to the channel formation region of the oxide 230b through the oxide 230c. Thus, the lower-resistance region which is formed in the vicinity of the surface of the oxide 230 in contact with the conductor 240 is not reduced and the oxygen vacancies formed in the channel formation region of the oxide 230 are efficiently compensated.

When the insulator 224 has an excess-oxygen region, excess oxygen contained in the insulator 224 is diffused into the oxide 230b through the oxide 230a in the oxide 230. In other words, excess oxygen can be supplied from the oxide 230a side. Accordingly, the reduction of the lower-resistance region which is formed in the vicinity of the surface of the oxide 230 in contact with the conductor 240 can be inhibited, and the oxygen vacancies formed in the channel formation region of the oxide 230 can be compensated.

The insulator 273 is preferably an aluminum oxide film formed using a sputtering apparatus. When the aluminum oxide film is formed as the insulator 273 under an oxygen gas atmosphere, excess oxygen can be introduced into the insulator 224 while the insulator 273 is formed.

The insulator 274 may be provided over the insulator 273. Note that like the insulator 273, the insulator 274 preferably has a function of inhibiting diffusion of oxygen.

Specifically, coverage with the insulator 273 deposited by a sputtering method is low. The insulator 274 is preferably deposited by an ALD method. This is because an ALD method can form a film having excellent thickness uniformity and excellent step coverage, which is less likely to be influenced by the shape of an object.

### <Application Example of Semiconductor Device>

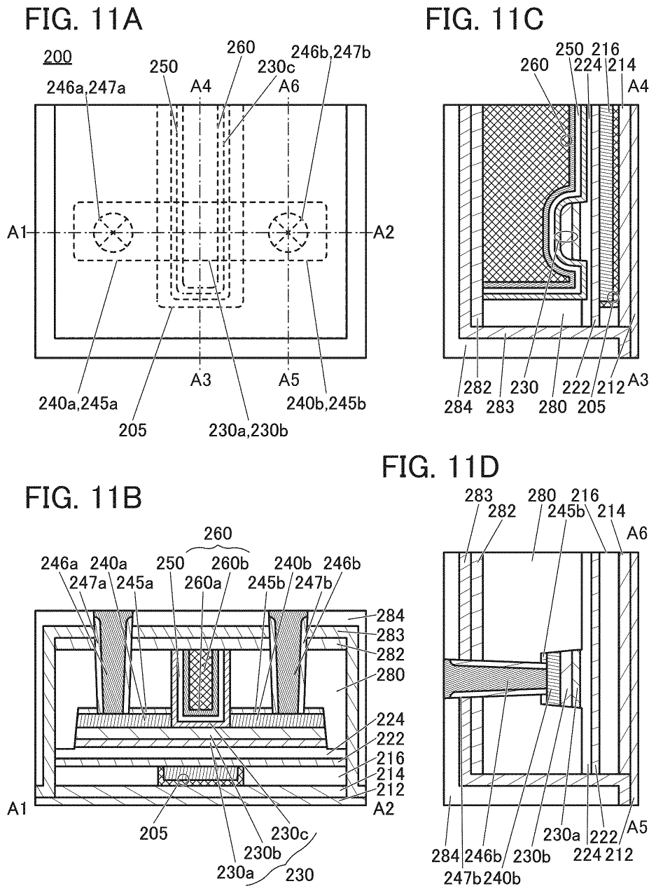

An example in which a stacked-layer structure of an interlayer film of one embodiment of the present invention and a plug are applied to the semiconductor device including the transistor 200 of this embodiment will be described below with reference to FIG. 11.

Here, FIG. 11A is a top view. FIG. 11B is a cross-sectional view corresponding to a portion indicated by dashed-dotted line A1-A2 in FIG. 11A. FIG. 11C is a cross-sectional view corresponding to a portion indicated by the dashed-dotted line A3-A4 in FIG. 11 A. FIG. 11D is a cross-sectional view corresponding to a portion indicated by the dashed-dotted line A5-A6 in FIG. 11A. For clarity of the drawing, some components are not illustrated in the top view of FIG. 11A.

In the semiconductor device illustrated in FIG. 11, the insulator 280, the insulator 282, an insulator 283, and the insulator 284 have opening portions that expose the transistor 200. In the opening portion, conductors 246 (a conductor 246a and a conductor 246b) that function as plugs electrically connected to the transistor 200 are provided. Insulators 247 are provided on the side surfaces of the opening portions.

Note that the conductors 246 each have a function of a plug or a wiring that is electrically connected to the transistor 200.

Furthermore, the semiconductor device illustrated in FIG. 11 includes an insulator 212 and the insulator 283, which function as barrier layers, over and under the transistor 200. The insulator 212 and the insulator 283 are in contact with each other at side of the transistor 200 or in an end portion region of the substrate. In other words, the semiconductor device illustrated in FIG. 11 has a structure in which the transistor 200 and the insulator 280 including the excess-oxygen region are sealed by barrier layers.

The region where the insulator 212 and the insulator 283 are in contact with each other may be provided along a scribe line. For example, when a plurality of transistors 200 are arranged in a matrix, a region where the insulator 212 and the insulator 283 are in contact with each other may be provided along the row and column where the plurality of transistors are aligned.

When the region where the insulator 212 and the insulator 283 are in contact with each other is provided at an end portion of the substrate, the region may be provided to overlap with the scribe line.

The insulator 283 is provided over the insulator 282. The insulator 284 is formed using a material having high etch rate selectivity ratio with respect to a conductor 248 when the conductor 248 is processed. Thus, the insulator 284 is provided over the insulator 283 if necessary.

The insulators 247 are preferably in contact with the insulator 283. When the insulators 247 and the insulator 283 are in contact with each other, the transistor 200 and the insulator 280 including an excess-oxygen region are sealed with the barrier layers.

Specifically, the insulators 247 are provided in contact with side walls of the openings in the insulator 283, the insulator 282, and the insulator 280, and the conductors 246 are formed in contact with these side surfaces. At least at part of the bottom portions of the openings, the transistor 200 is positioned and the conductors 246 are in contact with the transistor 200.

Note that in <Modification example of semiconductor device> and <Application example of semiconductor device>, the structure having the same functions as the components included in the semiconductor device described in <Structure example of semiconductor device>are denoted by the same reference numerals. Note that the materials described in detail in <Structure example of semiconductor device> can also be used as constituent materials of the semiconductor devices in this section.

According to the above, a highly reliable semiconductor device can be provided. In addition, a semiconductor device with favorable electrical characteristics can be provided. In addition, a semiconductor device that can be miniaturized or highly integrated can be provided. A semiconductor device with low power consumption can be provided.

The structure, method, and the like described above in this embodiment can be used in an appropriate combination with the structures, the methods, and the like described in the other embodiments and examples.

### Embodiment 3

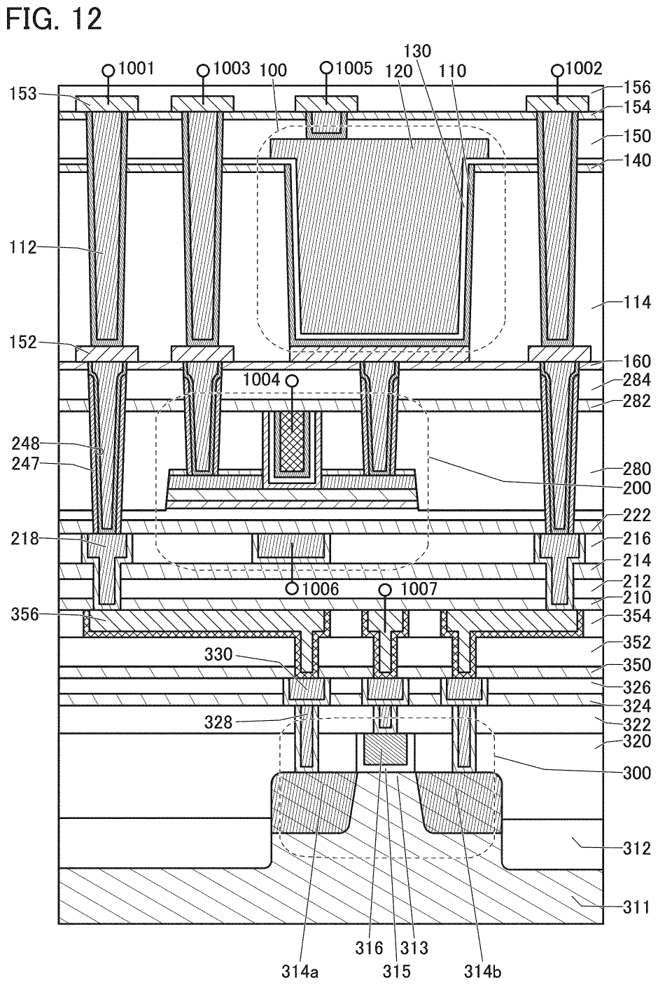

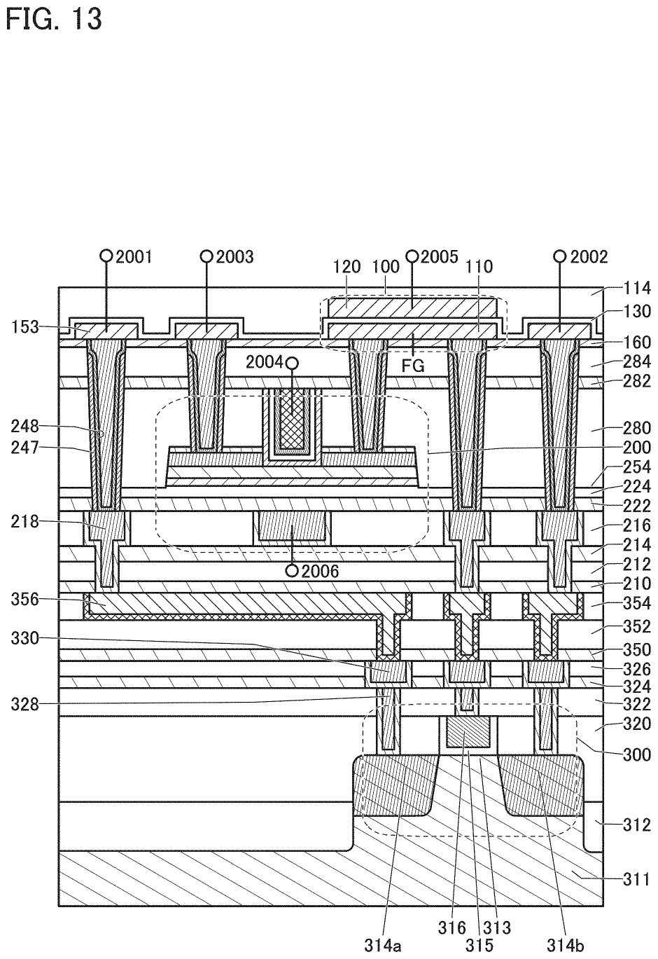

In this embodiment, one embodiment of a semiconductor device is described with reference to FIG. 12 and FIG. 13.

[Memory device 1]

FIG. 12 illustrates an example of a semiconductor device (memory device) in which a capacitor of one embodiment of the present invention is used. In the semiconductor device of one embodiment of the present invention, the transistor 200 is provided above a transistor 300, and a capacitor 100 is provided above the transistor 200. At least part of the capacitor 100 or the transistor 300 preferably overlaps with the transistor 200. Accordingly, an area occupied by the capacitor 100, the transistor 200, and the transistor 300 in a top view can be reduced, whereby the semiconductor device of this embodiment can be miniaturized or highly integrated. The semiconductor device of this embodiment can be applied to logic circuits typified by a CPU (Central Processing Unit) and a GPU (Graphics Processing Unit) and memory circuits typified by a DRAM (Dynamic Random Access Memory) and an NVM (Non-Volatile Memory), for example.

The transistor 200 described in the above embodiment can be used as the transistor 200. Therefore, for the transistor 200 and layers including the transistor 200, the description in the above embodiment can be referred to.

The transistor 200 is a transistor whose channel is formed in a semiconductor layer containing an oxide semiconductor. Since the transistor 200 has a low off-state current, a memory device including the transistor 200 can retain stored data for a long time. In other words, such a memory device does not require refresh operation or has an extremely low frequency of the refresh operation, which leads to a sufficient reduction in power consumption of the memory device. The transistor 200 exhibits favorable electrical characteristics at high temperatures, in comparison with a transistor including silicon in a semiconductor layer. For example, the transistor 200 has favorable electrical characteristics even in the temperature range of 125° C. to 150° C. Moreover, the transistor 200 has an on/off ratio of 10 digits or larger in the temperature range of 125° C. to 150° C. In other words, in comparison with a transistor including silicon in a semiconductor layer, the transistor 200 excels in characteristics such as on-state current and frequency characteristics at higher temperatures.

In the semiconductor device illustrated in FIG. 12, a wiring 1001 is electrically connected to a source of the transistor 300, a wiring 1002 is electrically connected to a drain of the transistor 300, and a wiring 1007 is electrically connected to a gate of the transistor 300. A wiring 1003 is electrically connected to one of the source and the drain of the transistor 200, a wiring 1004 is electrically connected to the first gate of the transistor 200, and a wiring 1006 is electrically connected to the second gate of the transistor 200. The other of the source and the drain of the transistor 200 is electrically connected to one electrode of the capacitor 100, and a wiring 1005 is electrically connected to the other electrode of the capacitor 100.

The semiconductor device illustrated in FIG. 12 has characteristics of being capable of retaining charge stored in the one electrode of the capacitor 100 by switching of the transistor 200; thus, writing, retention, and reading of data can be performed. The transistor 200 is an element in which a back gate is provided in addition to the source, the gate (top gate), and the drain. That is, the transistor 200 is a four-terminal element; hence, its input and output can be controlled independently of each other in a simpler manner than that in two-terminal elements typified by MRAM (Magnetoresistive Random Access Memory) utilizing MTJ (Magnetic Tunnel Junction) properties, ReRAM (Resistive Random Access Memory), and phase-change memory. In addition, the structure of MRAM, ReRAM, and phase-change memory may change at the atomic level when data is rewritten. By contrast, in the semiconductor device illustrated in FIG. 12, data rewriting is performed by charging or discharging of electrons with the transistor and the capacitor; thus, the semiconductor device has characteristics such as high write endurance and a few structure changes.

Furthermore, by arranging the semiconductor devices illustrated in FIG. 12 in a matrix, a memory cell array can be formed. In this case, the transistor 300 can be used for a read circuit, a driver circuit, or the like that is connected to the memory cell array. As described above, the semiconductor device illustrated in FIG. 12 constitutes the memory cell array. When the semiconductor device in FIG. 12 is used as a memory element, for example, an operating frequency of 200 MHz or higher is achieved at a driving voltage of 2.5 V and an evaluation environment temperature ranging from −40° C. to 85° C.

### <Transistor 300>

The transistor 300 is provided on a substrate 311 and includes a conductor 316 functioning as a gate electrode, an insulator 315 functioning as a gate insulator, a semiconductor region 313 that is part of the substrate 311, and a low-resistance region 314a and a low-resistance region 314b functioning as a source region and a drain region.

Here, the insulator 315 is placed over the semiconductor region 313, and the conductor 316 is placed over the insulator 315. The transistors 300 formed in the same layer are electrically isolated from one another by an insulator 312 functioning as an element isolation insulating layer. The insulator 312 can be formed using an insulator similar to an insulator 326 or the like described later. The transistor 300 may be a p-channel transistor or an n-channel transistor.

In the substrate 311, a region of the semiconductor region 313 where a channel is formed, a region in the vicinity thereof, the low-resistance region 314a and the low-resistance region 314b functioning as the source region and the drain region, and the like preferably contain a semiconductor such as a silicon-based semiconductor, further preferably single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing is used. Alternatively, the transistor 300 may be an HEMT (High Electron Mobility Transistor) using GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material used for the semiconductor region 313.

The conductor 316 functioning as the gate electrode can be formed using a semiconductor material such as silicon containing an element that imparts n-type conductivity, such as arsenic or phosphorus, or an element that imparts p-type conductivity, such as boron, or using a conductive material such as a metal material, an alloy material, or a metal oxide material.

Note that the work function depends on a material of the conductor; thus, the threshold voltage can be adjusted by changing the material of the conductor. Specifically, it is preferable to use a material such as titanium nitride or tantalum nitride for the conductor. Moreover, in order to obtain both conductivity and embeddability, it is preferable to use stacked layers of metal materials such as tungsten and aluminum for the conductor, and it is particularly preferable to use tungsten in terms of heat resistance.

Here, in the transistor 300 illustrated in FIG. 12, the semiconductor region 313 (part of the substrate 311) in which the channel is formed has a convex shape. Furthermore, the conductor 316 is provided so as to cover a side surface and the top surface of the semiconductor region 313 with the insulator 315 positioned therebetween. Such a transistor 300 is also referred to as a FIN-type transistor because it utilizes a convex portion of the semiconductor substrate. Note that an insulator functioning as a mask for forming the convex portion may be placed in contact with an upper portion of the convex portion. Furthermore, although the case where the convex portion is formed by processing part of the semiconductor substrate is described here, a semiconductor film having a convex shape may be formed by processing an SOI substrate.

Note that the transistor 300 illustrated in FIG. 12 is an example and the structure is not limited thereto; an appropriate transistor is used in accordance with a circuit structure or a driving method.

As illustrated in FIG. 12, the semiconductor device includes a stack of the transistor 300 and the transistor 200. For example, the transistor 300 can be formed using a silicon-based semiconductor material, and the transistor 200 can be formed using an oxide semiconductor. That is, in the semiconductor device in FIG. 12, a silicon-based semiconductor material and an oxide semiconductor can be used in different layers. The semiconductor device illustrated in FIG. 12 can be manufactured in a process similar to that employing a manufacturing apparatus that is used in the case of a silicon-based semiconductor material, and can be highly integrated.

### <Capacitor>

The capacitor 100 includes an insulator 114 over an insulator 160, an insulator 140 over the insulator 114, a conductor 110 positioned in an opening formed in the insulator 114 and the insulator 140, an insulator 130 over the conductor 110 and the insulator 140, a conductor 120 over the insulator 130, and an insulator 150 over the conductor 120 and the insulator 130. Here, at least parts of the conductor 110, the insulator 130, and the conductor 120 are positioned in the opening formed in the insulator 114 and the insulator 140.

The conductor 110 functions as a lower electrode of the capacitor 100, the conductor 120 functions as an upper electrode of the capacitor 100, and the insulator 130 functions as a dielectric of the capacitor 100. The capacitor 100 has a structure in which the upper electrode and the lower electrode face each other with the dielectric positioned therebetween on a side surface as well as the bottom surface of the opening in the insulator 114 and the insulator 140; thus, the capacitance per unit area can be increased. Thus, the deeper the opening is, the larger the capacitance of the capacitor 100 can be. Increasing the capacitance per unit area of the capacitor 100 in this manner can promote miniaturization or higher integration of the semiconductor device.

An insulator that can be used for the insulator 280 can be used for the insulator 114 and the insulator 150. The insulator 140 preferably functions as an etching stopper at the time of forming the opening in the insulator 114 and is formed using an insulator that can be used for the insulator 214.

The shape of the opening formed in the insulator 114 and the insulator 140 when seen from above may be a quadrangular shape, a polygonal shape other than a quadrangular shape, a polygonal shape with rounded corners, or a circular shape including an elliptical shape. Here, the area where the opening and the transistor 200 overlap with each other is preferably large in the top view. Such a structure can reduce the area occupied by the semiconductor device including the capacitor 100 and the transistor 200.

The conductor 110 is provided in contact with the opening formed in the insulator 140 and the insulator 114. The top surface of the conductor 110 is preferably substantially level with the top surface of the insulator 140. A conductor 152 provided over the insulator 160 is in contact with the bottom surface of the conductor 110. The conductor 110 is preferably deposited by an ALD method, a CVD method, or the like; for example, a conductor that can be used for the conductor 205 is used.

The insulator 130 is positioned to cover the conductor 110 and the insulator 140. The insulator 130 is preferably deposited by an ALD method or a CVD method, for example. The insulator 130 can be provided to have stacked layers or a single layer using, for example, silicon oxide, silicon oxynitride, silicon nitride oxide, silicon nitride, zirconium oxide, aluminum oxide, aluminum oxynitride, aluminum nitride oxide, aluminum nitride, hafnium oxide, hafnium oxynitride, hafnium nitride oxide, or hafnium nitride. As the insulator 130, an insulating film in which zirconium oxide, aluminum oxide, and zirconium oxide are stacked in this order can be used, for example.

For the insulator 130, a material with high dielectric strength, such as silicon oxynitride, or a high dielectric constant (high-k) material is preferably used. Alternatively, a stacked-layer structure using a material with high dielectric strength and a high dielectric constant (high-k) material may be employed.

As an insulator of a high dielectric constant (high-k) material (a material having a high relative permittivity), gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, and the like can be given. The use of such a high-k material can ensure sufficient capacitance of the capacitor 100 even when the insulator 130 has a large thickness. When the insulator 130 has a large thickness, leakage current generated between the conductor 110 and the conductor 120 can be inhibited.

Examples of the material with high dielectric strength include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin. For example, it is possible to use an insulating film in which silicon nitride (SiNₓ) deposited by an ALD method, silicon oxide (SiOₓ) deposited by a PEALD method, and silicon nitride (SiNₓ) deposited by an ALD method are stacked in this order. The use of such an insulator with high dielectric strength can increase the dielectric strength and inhibit electrostatic breakdown of the capacitor 100.

The conductor 120 is positioned to fill the opening formed in the insulator 140 and the insulator 114. The conductor 120 is electrically connected to the wiring 1005 through a conductor 112 and a conductor 153. The conductor 120 is preferably deposited by an ALD method, a CVD method, or the like and is formed using a conductor that can be used for the conductor 205, for example.

Since the transistor 200 has a structure in which an oxide semiconductor is used, the transistor 200 is highly compatible with the capacitor 100. Specifically, since the transistor 200 containing an oxide semiconductor has a low off-state current, a combination of the transistor 200 and the capacitor 100 enables stored data to be retained for a long time.

### <Wiring Layers>

Wiring layers provided with an interlayer film, a wiring, a plug, and the like may be provided between the structure bodies. A plurality of wiring layers can be provided in accordance with the design. Note that a plurality of conductors functioning as plugs or wirings are collectively denoted by the same reference numeral in some cases. Furthermore, in this specification and the like, a wiring and a plug electrically connected to the wiring may be a single component. That is, there are a case where part of a conductor functions as a wiring and a case where part of a conductor functions as a plug.

For example, an insulator 320, an insulator 322, an insulator 324, and the insulator 326 are stacked over the transistor 300 in this order as interlayer films.

Note that the insulator 322, the insulator 324, and the insulator 326 may each have the function of the adjustment layer described in the above embodiment.

Moreover, a conductor 328, a conductor 330, and the like that are electrically connected to the conductor 153 functioning as a terminal are embedded in the insulator 320, the insulator 322, the insulator 324, and the insulator 326. Note that the conductor 328 and the conductor 330 function as plugs or wirings.

The insulator functioning as an interlayer film may function as a planarization film that covers an uneven shape thereunder. For example, a top surface of the insulator 322 may be planarized by planarization treatment using a chemical mechanical polishing (CMP) method or the like to improve planarity.

A wiring layer may be provided over the insulator 326 and the conductor 330. For example, in FIG. 12, an insulator 350, an insulator 352, and an insulator 354 are provided to be stacked in this order.

The insulator 350, the insulator 352, and the insulator 354 may each have the function of the adjustment layer described in the above embodiment.

Furthermore, a conductor 356 is formed in the insulator 350, the insulator 352, and the insulator 354. The conductor 356 functions as a plug or a wiring.

An insulator 210, an insulator 212, the insulator 214, and the insulator 216 are stacked in this order over the insulator 354 and the conductor 356.

The insulator 210, the insulator 212, and the insulator 214 can each function as the adjustment layer described in the above embodiment.

A conductor 218, a conductor (the conductor 205) included in the transistor 200, and the like are embedded in the insulator 210, the insulator 212, the insulator 214, and the insulator 216. Note that the conductor 218 functions as a plug or a wiring that is electrically connected to the transistor 300.

The conductor 112, conductors (the conductor 120 and the conductor 110) included in the capacitor 100, and the like are embedded in the insulator 114, the insulator 140, the insulator 130, the insulator 150, and an insulator 154. Note that the conductor 112 functions as a plug or a wiring that electrically connects the capacitor 100, the transistor 200, or the transistor 300 to the conductor 153 functioning as a terminal.

The conductor 153 is provided over the insulator 154, and the conductor 153 is covered with an insulator 156. Here, the conductor 153 is in contact with a top surface of the conductor 112 and functions as a terminal of the capacitor 100, the transistor 200, or the transistor 300.

Examples of an insulator that can be used for an interlayer film include an oxide, a nitride, an oxynitride, a nitride oxide, a metal oxide, a metal oxynitride, and a metal nitride oxide, each of which has an insulating property. For example, when a material with a low relative permittivity is used for the insulator functioning as an interlayer film, the parasitic capacitance generated between wirings can be reduced. Accordingly, a material is preferably selected depending on the function of an insulator.

For example, for the insulator 320, the insulator 322, the insulator 326, the insulator 352, the insulator 354, the insulator 212, the insulator 114, the insulator 150, the insulator 156, and the like, an insulator with low relative permittivity is preferably used. For example, the insulators each preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulators each preferably have a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

It is preferable that the resistivity of an insulator provided over or under the conductor 152 or the conductor 153 be higher than or equal to 1.0×10¹² Ωcm and lower than or equal to 1.0×10¹⁵ Ωcm, preferably higher than or equal to 5.0×10¹² Ωcm and lower than or equal to 1.0×10¹⁴ Ωcm, further preferably higher than or equal to 1.0×10¹³ Ωcm and lower than or equal to 5.0×10¹³ Ωcm. The resistivity of the insulator provided over or under the conductor 152 or the conductor 153 is preferably within the above range because the insulator can disperse charges accumulated between the transistor 200, the transistor 300, the capacitor 100, and wirings such as the conductor 152 while maintaining the insulating property, and thus, poor characteristics and electrostatic breakdown of the transistor and the semiconductor device including the transistor due to the charges can be inhibited. For such an insulator, silicon nitride or silicon nitride oxide can be used. For example, the resistivity of the insulator 160 or the insulator 154 can be set within the above range.

When a transistor using an oxide semiconductor is surrounded by insulators having a function of inhibiting passage of oxygen and impurities such as hydrogen, the electrical characteristics of the transistor can be stable. Thus, an insulator having a function of inhibiting passage of oxygen and impurities such as hydrogen is used for the insulator 324, the insulator 350, the insulator 210, and like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum is used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; or silicon nitride can be used.

As the conductors that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

For example, for the conductor 328, the conductor 330, the conductor 356, the conductor 218, the conductor 112, the conductor 152, the conductor 153, and the like, a single layer or stacked layers of a conductive material such as a metal material, an alloy material, a metal nitride material, a metal oxide material, and the like that are formed using the above materials can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

### <Wiring or Plug in Layer Provided With Oxide Semiconductor>

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, the insulator 247 is preferably provided between the insulator 280 containing excess oxygen and the conductor 248 in FIG. 12. Since the insulator 247 is provided in contact with the insulator 282, the conductor 248 and the transistor 200 can be sealed by the insulators having a barrier property.

That is, the excess oxygen contained in the insulator 280 can be inhibited from being absorbed by the conductor 248 when the insulator 247 is provided. In addition, by including the insulator 247, the diffusion of hydrogen, which is an impurity, into the transistor 200 through the conductor 248 can be inhibited.

Here, the conductor 248 functions as a plug or a wiring that is electrically connected to the transistor 200 or the transistor 300.

Specifically, the insulator 247 is provided in contact with a side wall of the opening in the insulator 284, the insulator 282, and the insulator 280, and the conductor 248 is formed in contact with its side surface. The conductor 240 is located on at least part of the bottom portion of the opening, and the conductor 248 is in contact with the conductor 240.

The conductor 248 is preferably formed using a conductive material containing tungsten, copper, or aluminum as its main component. In addition, the conductor 248 may have a stacked-layer structure. Although the transistor 200 having a structure in which the conductor 248 have a stacked-layer structure of two layers is illustrated, the present invention is not limited thereto. For example, the conductor 248 may be provided as a single layer or to have a stacked-layer structure of three or more layers.

In the case where the conductor 248 has a stacked-layer structure, a conductive material having a function of inhibiting passage of impurities such as water and hydrogen is preferably used as a conductor that is in contact with the conductor 240 and in contact with the insulator 280, the insulator 282, and the insulator 284 with the insulator 247 therebetween. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. The use of the conductive material can prevent oxygen added to the insulator 280 from being absorbed by the conductor 248. Moreover, impurities such as water and hydrogen contained in a layer above the insulator 284 can be inhibited from diffusing into the oxide 230 through the conductor 248.

As the insulator 247, for example, an insulator that can be used as the insulator 214, or the like may be used. The insulator 247 can inhibit diffusion of impurities such as water and hydrogen contained in the insulator 280 and the like into the oxide 230 through the conductor 248. In addition, oxygen contained in the insulator 280 can be prevented from being absorbed by the conductor 248.

Although not illustrated, the conductor 152 functioning as a wiring may be placed in contact with the top surface of the conductor 248. For the conductor functioning as a wiring, a conductive material containing tungsten, copper, or aluminum as its main component is preferably used. Furthermore, the conductor may have a stacked-layer structure and may be a stack of titanium or titanium nitride and any of the above conductive materials, for example. Note that the conductor may be formed to be embedded in an opening provided in an insulator.

The above is the description of the structure example. With the use of this structure, a semiconductor device using a transistor including an oxide semiconductor can be miniaturized or highly integrated. Alternatively, a change in electrical characteristics can be inhibited and reliability can be improved in a semiconductor device using a transistor including an oxide semiconductor. Alternatively, a transistor including an oxide semiconductor and having a high on-state current can be provided. Alternatively, a transistor including an oxide semiconductor and having a low off-state current can be provided. Alternatively, a semiconductor device with low power consumption can be provided.

### [Memory Device 2]

FIG. 13 illustrates an example of a semiconductor device (memory device) using the semiconductor device of one embodiment of the present invention. Like the semiconductor device illustrated in FIG. 12, the semiconductor device illustrated in FIG. 13 includes the transistor 200, the transistor 300, and the capacitor 100. Note that the semiconductor device illustrated in FIG. 13 differs from the semiconductor device illustrated in FIG. 12 in that the capacitor 100 is a planar capacitor and that the transistor 200 is electrically connected to the transistor 300.

In the semiconductor device of one embodiment of the present invention, the transistor 200 is provided above the transistor 300, and the capacitor 100 is provided above the transistor 300 and the transistor 200. At least part of the capacitor 100 or the transistor 300 preferably overlaps with the transistor 200. Accordingly, an area occupied by the capacitor 100, the transistor 200, and the transistor 300 in a top view can be reduced, whereby the semiconductor device of this embodiment can be miniaturized or highly integrated.

Note that the transistor 200 and the transistor 300 mentioned above can be used as the transistor 200 and the transistor 300, respectively. Therefore, the above description can be referred to for the transistor 200, the transistor 300, and the layers including them.

In the semiconductor device illustrated in FIG. 13, a wiring 2001 is electrically connected to the source of the transistor 300, and a wiring 2002 is electrically connected to the drain of the transistor 300. A wiring 2003 is electrically connected to one of the source and the drain of the transistor 200, a wiring 2004 is electrically connected to the first gate of the transistor 200, and a wiring 2006 is electrically connected to the second gate of the transistor 200. The gate of the transistor 300 and the other of the source and the drain of the transistor 200 are electrically connected to one electrode of the capacitor 100, and a wiring 2005 is electrically connected to the other electrode of the capacitor 100. Note that a node where the gate of the transistor 300, the other of the source and the drain of the transistor 200, and the one electrode of the capacitor 100 are connected to one another is hereinafter referred to as a node FG in some cases.

The semiconductor device illustrated in FIG. 13 is capable of retaining the potential of the gate of the transistor 300 (the node FG) by switching of the transistor 200; thus, data writing, retention, and reading can be performed.

By arranging the semiconductor devices illustrated in FIG. 13 in a matrix, a memory cell array can be formed.

The layer including the transistor 300 has the same structure as that in the semiconductor device illustrated in FIG. 12, and therefore, the above description can be referred to for the structure below the insulator 354.

The insulator 210, the insulator 212, the insulator 214, and the insulator 216 are positioned over the insulator 354. Here, an insulator having a function of inhibiting passage of oxygen and impurities such as hydrogen is used for the insulator 210, as for the insulator 350 and the like.

The conductor 218 is embedded in the insulator 210, the insulator 212, the insulator 214, and the insulator 216. The conductor 218 functions as a plug or a wiring that is electrically connected to the capacitor 100, the transistor 200, or the transistor 300. For example, the conductor 218 is electrically connected to the conductor 316 functioning as the gate electrode of the transistor 300.

Note that the conductor 248 functions as a plug or a wiring that is electrically connected to the transistor 200 or the transistor 300. For example, the conductor 248 electrically connects the conductor 240b functioning as the other of the source and the drain of the transistor 200 and the conductor 110 functioning as one electrode of the capacitor 100 through the conductor 248.

The planar capacitor 100 is provided above the transistor 200. The capacitor 100 includes the conductor 110 functioning as a first electrode, the conductor 120 functioning as a second electrode, and the insulator 130 functioning as a dielectric. Note that as the conductor 110, the conductor 120, and the insulator 130, those described above in Memory device 1 can be used.

The conductor 153 and the conductor 110 are provided in contact with the top surface of the conductor 248. The conductor 153 is in contact with the top surface of the conductor 248 and functions as a terminal of the transistor 200 or the transistor 300.

The conductor 153 and the conductor 110 are covered with the insulator 130, and the conductor 120 is positioned to overlap with the conductor 110 with the insulator 130 therebetween. In addition, the insulator 114 is positioned over the conductor 120 and the insulator 130.

Although FIG. 13 illustrates an example in which a planar capacitor is used as the capacitor 100, the semiconductor device of this embodiment is not limited thereto. For example, the capacitor 100 may be a cylinder capacitor 100 like that illustrated in FIG. 12.

### [Memory Device 3]

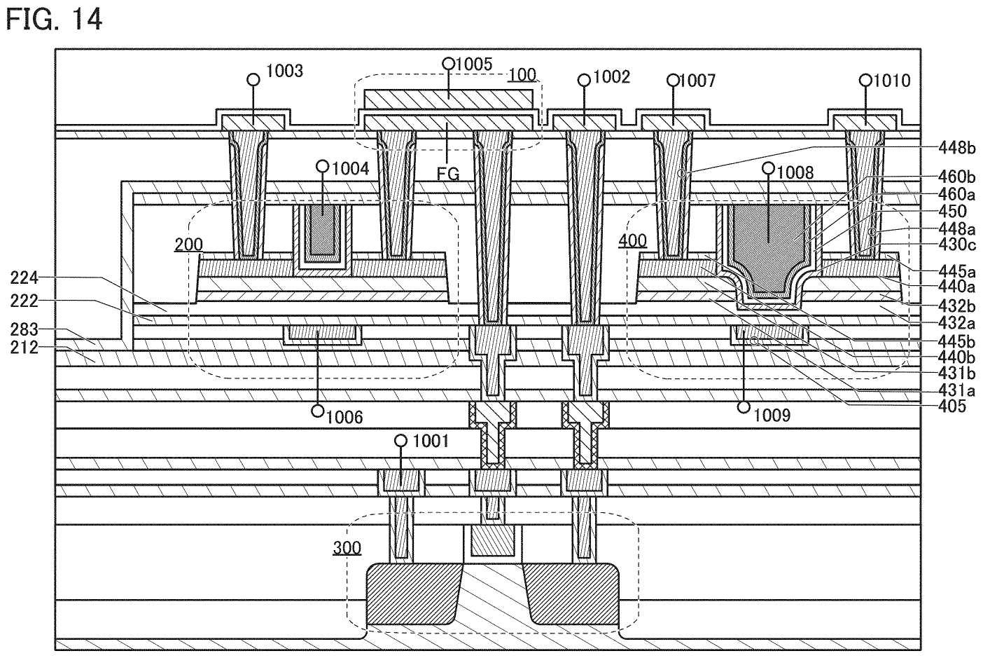

FIG. 14 illustrates an example of a memory device using the semiconductor device of one embodiment of the present invention. The memory device illustrated in FIG. 14 includes a transistor 400 in addition to the semiconductor device including the transistor 200, the transistor 300, and the capacitor 100 illustrated in FIG. 13.

The transistor 400 can control a second gate voltage of the transistor 200. For example, a first gate and a second gate of the transistor 400 are diode-connected to a source of the transistor 400, and the source of the transistor 400 is connected to the second gate of the transistor 200. When a negative potential of the second gate of the transistor 200 is retained in this structure, the first gate-source voltage and the second gate-source voltage of the transistor 400 become 0 V. In the transistor 400, a drain current at the time when a second gate voltage and a first gate voltage are 0 V is extremely low; thus, the negative potential of the second gate of the transistor 200 can be maintained for a long time even without power supply to the transistor 200 and the transistor 400. Accordingly, the memory device including the transistor 200 and the transistor 400 can retain stored data for a long time.

Hence, in FIG. 14, the wiring 1001 is electrically connected to the source of the transistor 300, and the wiring 1002 is electrically connected to the drain of the transistor 300. The wiring 1003 is electrically connected to one of the source and the drain of the transistor 200, the wiring 1004 is electrically connected to the gate of the transistor 200, and the wiring 1006 is electrically connected to a second gate (back gate) of the transistor 200. A gate of the transistor 300 and the other of the source and the drain of the transistor 200 are electrically connected to one electrode of the capacitor 100. The wiring 1005 is electrically connected to the other electrode of the capacitor 100. The wiring 1007 is electrically connected to the source of the transistor 400, a wiring 1008 is electrically connected to a gate of the transistor 400, a wiring 1009 is electrically connected to a second gate (back gate) of the transistor 400, and a wiring 1010 is electrically connected to the drain of the transistor 400. The wiring 1006, the wiring 1007, the wiring 1008, and the wiring 1009 are electrically connected to each other.

When the memory devices illustrated in FIG. 14 are arranged in a matrix like the memory devices illustrated in FIG. 12 and FIG. 13, a memory cell array can be formed. Note that one transistor 400 can control the second gate voltages of a plurality of transistors 200. For this reason, the number of transistors 400 is preferably smaller than the number of transistors 200.

### <Transistor 400>

The transistor 400 and the transistors 200 are formed in the same layer and thus can be fabricated in parallel. The transistor 400 includes a conductor 460 (a conductor 460a and a conductor 460b) functioning as a first gate electrode, a conductor 405 functioning as a second gate electrode, the insulator 222, the insulator 224, and an insulator 450 functioning as a gate insulating layer, an oxide 430c including a region where a channel is formed, a conductor 440a, an oxide 431a, and an oxide 431b functioning as one of a source and a drain, a conductor 440b, an oxide 432a, and an oxide 432b functioning as the other of the source and the drain, and an insulator 445a and an insulator 445b functioning as a barrier layer.

In the transistor 400, the conductor 405 is in the same layer as the conductor 205. The oxide 431a and the oxide 432a are in the same layer as the oxide 230a, and the oxide 431b and the oxide 432b are in the same layer as the oxide 230b. The conductor 440 (the conductor 440a and the conductor 440b) is in the same layer as the conductor 240. The insulator 445 (the insulator 445a and the insulator 445b) is in the same layer as the insulator 245. The oxide 430c is in the same layer as the oxide 230c. The insulator 450 is in the same layer as the insulator 250. The conductor 460 is in the same layer as the conductor 260.

Note that the components formed in the same layer can be formed at the same time. For example, the oxide 430c can be formed by processing an oxide film to be the oxide 230c.

In the oxide 430c functioning as an active layer of the transistor 400, oxygen vacancies and impurities such as hydrogen and water are reduced, as in the oxide 230 or the like.

Accordingly, the threshold voltage of the transistor 400 can be higher than 0 V, the off-state current can be reduced, and the drain current at the time when the second gate voltage and the first gate voltage are 0 V can be extremely low.

This embodiment can be implemented in an appropriate combination with the structures described in the other embodiments, Example, and the like.

### Embodiment 4

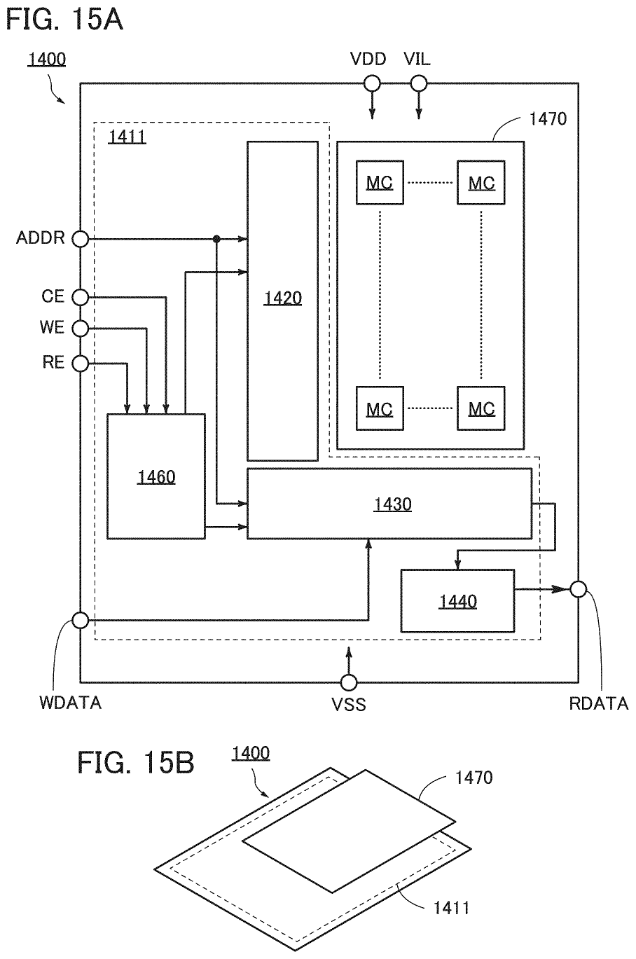

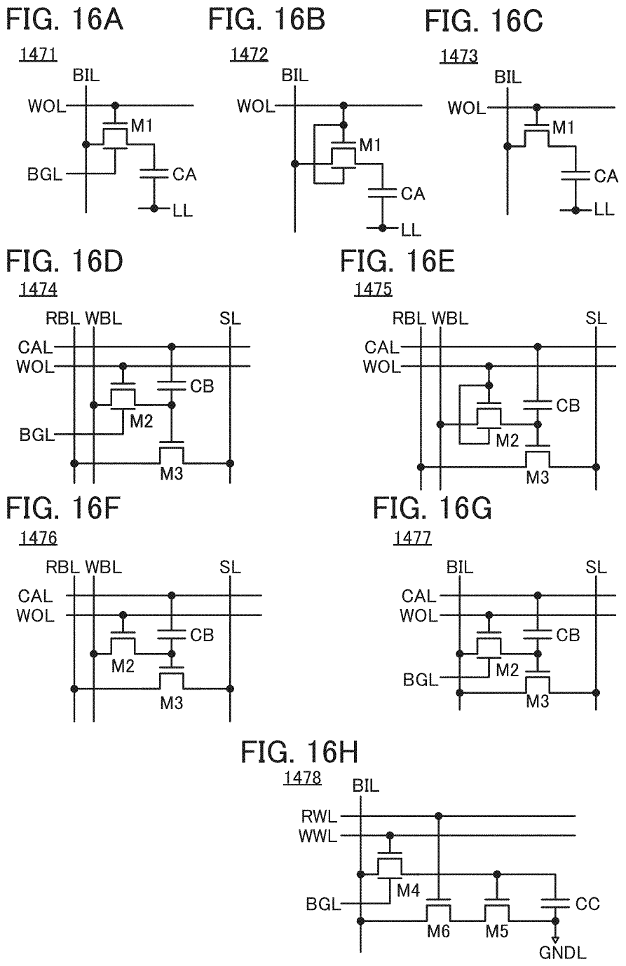

In this embodiment, a memory device of one embodiment of the present invention including a transistor in which oxide is used as a semiconductor (hereinafter referred to as an OS transistor in some cases) and a capacitor (hereinafter such a memory device is also referred to as an OS memory device in some cases) will be described with reference to FIG. 15 and FIG. 16. The OS memory device includes at least a capacitor and an OS transistor that controls the charging and discharging of the capacitor. Since the OS transistor has an extremely low off-state current, the OS memory device has excellent retention characteristics and thus can function as a nonvolatile memory.

### <Structure Example of Memory Device>

FIG. 15A illustrates a structure example of the OS memory device. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and will be described later in detail. The amplified data signal is output as a data signal RDATA to the outside of the memory device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the memory device 1400. Control signals (CE, WE, and RE), an address signal ADDR, and a data signal WDATA are also input to the memory device 1400 from the outside. The address signal ADDR is input to the row decoder and the column decoder, and the data signal WDATA is input to the write circuit.

The control logic circuit 1460 processes the control signals (CE, WE, and RE) input from the outside, and generates control signals for the row decoder and the column decoder. CE is a chip enable signal, WE is a write enable signal, and RE is a read enable signal. Signals processed by the control logic circuit 1460 are not limited thereto, and other control signals may be input as necessary.

The memory cell array 1470 includes a plurality of memory cells MC arranged in a matrix and a plurality of wirings. Note that the number of the wirings that connect the memory cell array 1470 to the row circuit 1420 depends on the structure of the memory cell MC, the number of the memory cells MC in a column, and the like. The number of the wirings that connect the memory cell array 1470 to the column circuit 1430 depends on the structure of the memory cell MC, the number of the memory cells MC in a row, and the like.

Note that FIG. 15A shows an example in which the peripheral circuit 1411 and the memory cell array 1470 are formed on the same plane; however, this embodiment is not limited thereto. For example, as shown in FIG. 15B, the memory cell array 1470 may be provided over a part of the peripheral circuit 1411 so that they overlap. For example, the sense amplifier may be provided below the memory cell array 1470 so that they overlap with each other.

Structure examples of a memory cell in FIG. 16 that can be used in the memory cell MC are described.

### [DOSRAM]

FIG. 16A to FIG. 16C each illustrate a circuit structure example of a memory cell of a DRAM. In this specification and the like, a DRAM using a memory cell including one OS transistor and one capacitor is referred to as DOSRAM (Dynamic Oxide Semiconductor Random Access Memory) in some cases. A memory cell 1471 in FIG. 16A includes a transistor M1 and a capacitor CA. Note that the transistor M1 includes a gate (also referred to as a top gate in some cases) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. In the time of data writing and data reading, the wiring LL may be at a ground potential or a low-level potential. The wiring BGL functions as a wiring for applying a potential to the back gate of the transistor M1. Applying a given potential to the wiring BGL can increase or decrease the threshold voltage of the transistor M1.

Here, the memory cell 1471 shown in FIG. 16A corresponds to the memory device illustrated in FIG. 12. That is, the transistor M1, the capacitor CA, the wiring BIL, the wiring WOL, the wiring BGL, and the wiring LL correspond to the transistor 200, the capacitor 100, the wiring 1003, the wiring 1004, the wiring 1006, and the wiring 1005, respectively. Note that the transistor 300 shown in FIG. 12 corresponds to a transistor provided in the peripheral circuit 1411 of the memory device 1400 illustrated in FIG. 15A and FIG. 15B.

The memory cell MC is not limited to the memory cell 1471, and the circuit structure can be changed. For example, like a memory cell 1472 in FIG. 16B, a structure may be used in which the back gate of the transistor M1 is connected not to the wiring BGL but to the wiring WOL in the memory cell MC. As another example, the memory cell MC may be configured with a single-gate transistor, that is, the transistor M1 that does not have a back gate, like a memory cell 1473 in FIG. 16C.

In the case where the semiconductor device described in the above embodiments is used in the memory cell 1471 and the like, the transistor 200 can be used as the transistor M1, and the capacitor 100 can be used as the capacitor CA. The use of an OS transistor as the transistor M1 enables the leakage current of the transistor M1 to be extremely low. That is, with the use of the transistor M1, written data can be retained for a long time, and thus the frequency of the refresh operation for the memory cell can be decreased, or the refresh operation of the memory cell can be omitted. Since the transistor M1 has an extremely low leakage current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. Thus, the bit line capacitance can be small, and the storage capacitance of the memory cell can be reduced.

### [NOSRAM]

FIG. 16D to FIG. 16G show circuit structure examples of a gain-cell type memory cell including two transistors and one capacitor. A memory cell 1474 shown in FIG. 16D includes a transistor M2, a transistor M3, and a capacitor CB. Note that the transistor M2 includes a front gate (simply referred to as a gate in some cases) and a back gate. In this specification and the like, a memory device including a gain-cell memory cell using an OS transistor as the transistor M2 is referred to as NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. A gate of the transistor M2 is connected to the wiring WOL. A back gate of the transistor M2 is connected to the wiring BGL. A second terminal of the capacitor CB is connected to a wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing and data reading, a high-level potential is preferably applied to the wiring CAL. In the time of data retaining, a low-level potential is preferably applied to the wiring CAL. The wiring BGL functions as a wiring for applying a potential to the back gate of the transistor M2. By application of a given potential to the wiring BGL, the threshold voltage of the transistor M2 can be increased or decreased.

Here, the memory cell 1474 shown in FIG. 16D corresponds to the memory device shown in FIG. 13. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 2003, the wiring 2004, the wiring 2006, the wiring 2005, the wiring 2002, and the wiring 2001, respectively.

The memory cell MC is not limited to the memory cell 1474, and the circuit structure can be changed as appropriate. For example, like a memory cell 1475 in FIG. 16E, a structure may be used in which the back gate of the transistor M2 is connected not to the wiring BGL but to the wiring WOL in the memory cell MC. Alternatively, for example, like a memory cell 1476 in FIG. 16F, the memory cell MC may be a memory cell including a single-gate transistor, that is, the transistor M2 that does not include a back gate. For example, the memory cell MC may have a structure in which the wiring WBL and the wiring RBL are combined into one wiring BIL as in a memory cell 1477 in FIG. 16G.

In the case where the semiconductor device described in the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the leakage current of the transistor M2 can be extremely low. That is, with the use of the transistor M2, written data can be retained for a long time, and thus the frequency of the refresh operation for the memory cell can be decreased. Alternatively, the refresh operation of the memory cell can be omitted. In addition, since the transistor M2 has an extremely low leakage current, multi-level data or analog data can be retained in the memory cell 1474. The same applies to the memory cell 1475 to the memory cell 1477.

Note that the transistor M3 may be a transistor containing silicon in a channel formation region (hereinafter also referred to as a Si transistor in some cases). The conductivity type of the Si transistor may be of either an n-channel type or a p-channel type. The Si transistor has higher field-effect mobility than the OS transistor in some cases. Therefore, a Si transistor may be used as the transistor M3 functioning as a reading transistor. Furthermore, the transistor M2 can be provided to be stacked over the transistor M3 when a Si transistor is used as the transistor M3; therefore, the area occupied by the memory cell can be reduced, leading to high integration of the memory device.

The transistor M3 may be an OS transistor. When an OS transistor is used as each of the transistor M2 and the transistor M3, the circuit of the memory cell array 1470 can be formed using only n-channel transistors.

FIG. 16H shows an example of a gain-cell type memory cell including three transistors and one capacitor. A memory cell 1478 in FIG. 16H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor including a back gate that is electrically connected to the wiring BGL. Note that the back gate and the gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors. In that case, the circuit of the memory cell array 1470 can be configured using only n-channel transistors.

In the case where the semiconductor device described in the above embodiments is used in the memory cell 1478, the transistor 200 can be used as the transistor M4, the transistor 300 can be used as the transistor M5 and the transistor M6, and the capacitor 100 can be used as the capacitor CC. When an OS transistor is used as the transistor M4, the leakage current of the transistor M4 can be extremely low.

Note that the structures of the peripheral circuit 1411, the memory cell array 1470, and the like described in this embodiment are not limited to the above. Positions and functions of these circuits, wirings connected to the circuits, circuit elements, and the like can be changed, deleted, or added as needed.

The structure described in this embodiment can be used in an appropriate combination with the structures described in the other embodiments, example, and the like.

### Embodiment 5

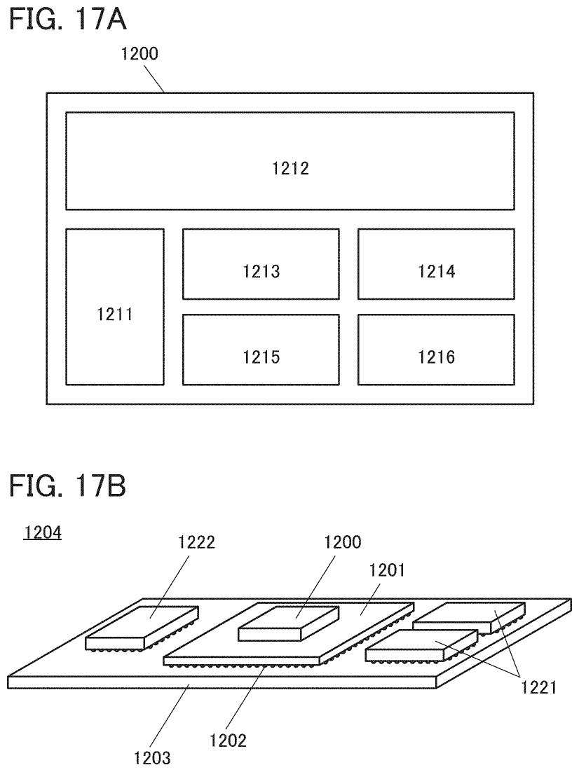

In this embodiment, an example of a chip 1200 on which a semiconductor device of the present invention is mounted is described using FIG. 17. A plurality of circuits (systems) are mounted on the chip 1200. The technique for integrating a plurality of circuits (systems) on one chip as described above is referred to as system on chip (SoC) in some cases.

As illustrated in FIG. 17A, the chip 1200 includes a CPU 1211, a GPU 1212, one or more of analog arithmetic units 1213, one or more of memory controllers 1214, one or more of interfaces 1215, one or more of network circuits 1216, and the like.

A bump (not illustrated) is provided on the chip 1200 and is connected to a first surface of a printed circuit board (PCB) 1201 as shown in FIG. 17B. A plurality of bumps 1202 are provided on the rear side of the first surface of the PCB 1201, and the PCB 1201 is connected to a motherboard 1203.

A memory device such as a DRAM 1221 or a flash memory 1222 may be provided over the motherboard 1203. For example, the DOSRAM described in the above embodiment can be used as the DRAM 1221. For example, the NOSRAM described in the above embodiment can be used as the flash memory 1222.

The CPU 1211 preferably includes a plurality of CPU cores. Furthermore, the GPU 1212 preferably includes a plurality of GPU cores. The CPU 1211 and the GPU 1212 may each include a memory for storing data temporarily. Alternatively, a common memory for the CPU 1211 and the GPU 1212 may be provided in the chip 1200. The NOSRAM or the DOSRAM described above can be used as the memory. The GPU 1212 is suitable for parallel computation of a number of data and thus can be used for image processing or product-sum operation. When an image processing circuit or a product-sum operation circuit including an oxide semiconductor of the present invention is provided in the GPU 1212, image processing and product-sum operation can be performed with low power consumption.

Since the CPU 1211 and the GPU 1212 are provided in the same chip, a wiring between the CPU 1211 and the GPU 1212 can be shortened; accordingly, the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. The analog arithmetic unit 1213 may include the above-described product-sum operation circuit.

The memory controller 1214 includes a circuit functioning as a controller of the DRAM 1221 and a circuit functioning as the interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, USB (Universal Serial Bus), HDMI (registered trademark) (High-Definition Multimedia Interface), or the like can be used.

The network circuit 1216 includes a circuit for a network such as a LAN (Local Area Network). The network circuit 1216 may include a circuit for network security.

The circuits (systems) can be formed in the chip 1200 in the same manufacturing process. Thus, even when the number of circuits needed for the chip 1200 is increased, there is no need to increase the number of steps in the manufacturing process; thus, the chip 1200 can be manufactured at low cost.

The motherboard 1203 provided with the PCB 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. Furthermore, the GPU module 1204 is excellent in image processing, and thus is suitably used in a portable electronic device such as a smartphone, a tablet terminal, a laptop PC, or a portable (mobile) game console. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

The structure described in this embodiment can be used in an appropriate combination with the structures described in the other embodiments, example, and the like.

### Embodiment 6

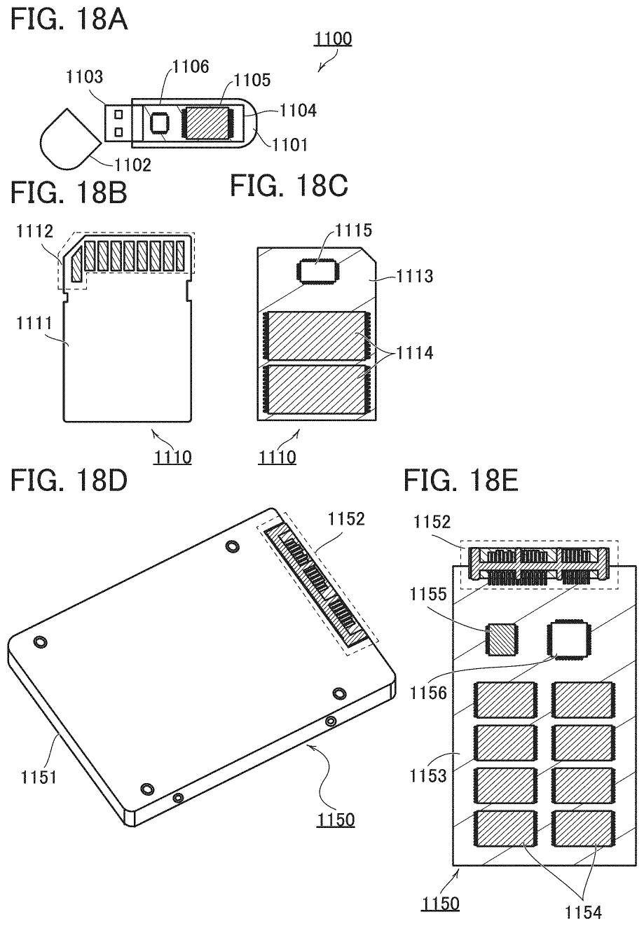

In this embodiment, application examples of the memory device using the semiconductor device described in the above embodiment are described. The semiconductor device described in the above embodiment can be applied to, for example, memory devices of a variety of electronic devices (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to removable memory devices such as memory cards (e.g., SD cards), USB memories, and SSDs (solid state drives). FIG. 18 schematically illustrates some structure examples of removable memory devices. The semiconductor device described in the above embodiment is processed into a packaged memory chip and used in a variety of storage devices and removable memories, for example.

FIG. 18A is a schematic view of a USB memory. A USB memory 1100 includes a housing 1101, a cap 1102, a USB connector 1103, and a substrate 1104. The substrate 1104 is held in the housing 1101. For example, a memory chip 1105 and a controller chip 1106 are attached to the substrate 1104. The semiconductor device described in the above embodiment can be incorporated in the memory chip 1105 or the like on the substrate 1104.

FIG. 18B is a schematic external view of an SD card, and FIG. 18C is a schematic view of the internal structure of the SD card. An SD card 1110 includes a housing 1111, a connector 1112, and a substrate 1113. The substrate 1113 is held in the housing 1111. For example, a memory chip 1114 and a controller chip 1115 are attached to the substrate 1113. When the memory chip 1114 is also provided on the rear surface side of the substrate 1113, the capacity of the SD card 1110 can be increased. In addition, a wireless chip with a radio communication function may be provided on the substrate 1113. With this, data can be read from and written in the memory chip 1114 by radio communication between a host device and the SD card 1110. The semiconductor device described in the above embodiment can be incorporated in the memory chip 1114 or the like on the substrate 1113.

FIG. 18D is a schematic external view of an SSD, and FIG. 18E is a schematic view of the internal structure of the SSD. An SSD 1150 includes a housing 1151, a connector 1152, and a substrate 1153. The substrate 1153 is held in the housing 1151. For example, a memory chip 1154, a memory chip 1155, and a controller chip 1156 are attached to the substrate 1153. The memory chip 1155 is a work memory for the controller chip 1156, and a DOSRAM chip may be used, for example. When the memory chip 1154 is also provided on the rear surface side of the substrate 1153, the capacity of the SSD 1150 can be increased. The semiconductor device described in the above embodiment can be incorporated in the memory chip 1154 or the like on the substrate 1153.

This embodiment can be implemented in an appropriate combination with the structures described in the other embodiments, example, and the like.

### Embodiment 7

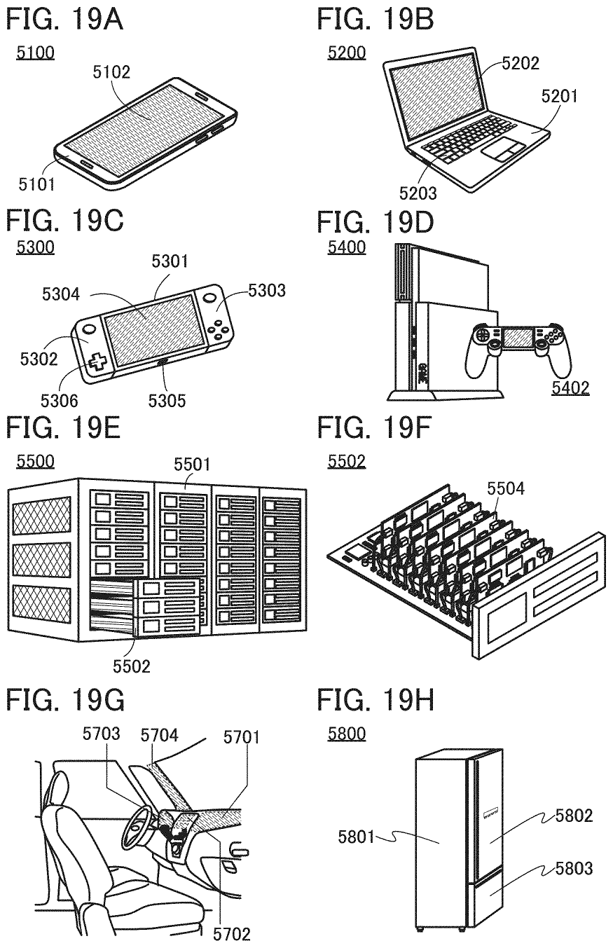

The semiconductor device of one embodiment of the present invention can be used as a processor such as a CPU and a GPU or a chip. FIG. 19 illustrates specific examples of electronic devices including processors such as CPUs and GPUs, or chips of one embodiment of the present invention.

### <Electronic Device and System>

The GPU or the chip of one embodiment of the present invention can be mounted on a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. In addition, when the GPU or the chip of one embodiment of the present invention is provided in the electronic device, the electronic device can include artificial intelligence.

The electronic device of one embodiment of the present invention may include an antenna. When a signal is received by the antenna, a video, data, or the like can be displayed on the display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 19 illustrates examples of electronic devices.

### [Information Terminal]

FIG. 19A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the content of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 19B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with use of the notebook information terminal 5200, novel artificial intelligence can be developed.

Note that although FIG. 19A and FIG. 19B illustrate a smartphone and a notebook information terminal, respectively, as examples of the electronic device in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machines]

FIG. 19C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not shown), an image to be output to the display portion 5304 can be output to another video device (not shown). In that case, the housing 5302 and the housing 5303 can each function as an operating unit. Thus, a plurality of players can perform a game at the same time. The chip described in the above embodiment can be incorporated into the chip provided on a substrate in the housing 5301, the housing 5302 and the housing 5303.

FIG. 19D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, questions posed by the player, the progress of the game, time, and actions and words of game characters can be changed for various expressions.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are shown as examples of game machines in FIG. 19C and FIG. 19D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

[Large computer]

The GPU or the chip of one embodiment of the present invention can be used in a large computer.

FIG. 19E illustrates a supercomputer 5500 as an example of a large computer. FIG. 19F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip shown in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is shown as an example of a large computer in FIG. 19E and FIG. 19F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 19G illustrates an area around a windshield inside an automobile, which is an example of a moving vehicle. FIG. 19G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. The content, layout, or the like of the display on the display panels can be changed appropriately to suit the user's preferences, so that the design can be improved. The display panel 5701 to the display panel 5703 can also be used as lighting devices.

The display panel 5704 can compensate for view obstructed by the pillar (a blind spot) by showing an image taken by an imaging device (not shown) provided for the automobile. That is, displaying an image taken by the imaging device provided outside the automobile leads to compensation for the blind spot and an increase in safety. In addition, display of an image that complements the area that cannot be seen makes it possible to confirm safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. The display panel 5701 to the display panel 5704 may display information regarding navigation, risk prediction, and the like.

Although an automobile is described above as an example of a moving vehicle, moving vehicles are not limited to an automobile. Examples of a moving vehicle include a train, a monorail train, a ship, and a flying object (a helicopter, an unmanned aircraft (a drone), an airplane, and a rocket), and these moving vehicles can include a system utilizing artificial intelligence when equipped with the chip of one embodiment of the present invention.

### [Household Appliance]

FIG. 19H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be obtained. Utilizing the artificial intelligence enables the electric refrigerator-freezer 5800 to have a function of automatically making a menu based on foods stored in the electric refrigerator-freezer 5800 and the food expiration dates, for example, a function of automatically adjusting the temperature to be appropriate for the foods stored in the electric refrigerator-freezer 5800, and the like.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic device and the functions of the electronic device, the application example of the artificial intelligence and its effects, and the like described in this embodiment can be combined as appropriate with the description of another electronic device.

This embodiment can be implemented in an appropriate combination with the structures described in the other embodiments, example, and the like.

### EXAMPLE

In this example, a semiconductor device including a stack of a first transistor and a second transistor was fabricated as a sample 1 A. After that, cross-sectional observation was performed on the semiconductor device. Note that the transistor 200 illustrated in FIG. 2 was formed as each of the first transistor and the second transistor.

### <Method for Fabricating Sample>

A method for fabricating the sample 1 A is described below.

First, a 1st layer including the first transistor 200 was formed over a base.

Specifically, for the sample 1 A, an In—Ga—Zn oxide was deposited as a first oxide (the oxide film 230A) to be the oxide 230a by a sputtering method using a target with In: Ga:Zn=1:3:4 [atomic ratio]. Then, over the first oxide, an In—Ga—Zn oxide was deposited by a sputtering method using a target with In:Ga:Zn=4:2:4.1 [atomic ratio] and an In-Ga-Zn oxide was deposited by a sputtering method using a target with In:Ga:Zn=1:3:4 [atomic ratio], whereby a stacked-layer structure of two layers was formed as a second oxide (the oxide film 230B) to be the oxide 230b. Note that the first oxide and the second oxide were successively deposited.

Subsequently, for the sample 1 A, a tungsten film to be the conductor 240 was deposited over the second oxide. After that, the conductor, the second oxide, and the first oxide were processed using a hard mask, so that the oxide 230a, the oxide 230b, the conductive layer 240B, and an insulating layer to be the insulating layer 245 were formed.

Next, for the sample 1 A and a sample 1 B, a silicon oxynitride film to be the insulator 280 was deposited. Then, the silicon oxynitride film was polished by performing CMP treatment to planarize the surface of the silicon oxynitride film, whereby the insulator 280 was formed.

After that, for the sample 1 A, an opening portion was formed in the silicon oxynitride film to be the insulator 280. Then, the conductive layer 240B exposed at the bottom surface of the opening portion was removed to form the conductor 240a and the conductor 240b.

Then, for the sample 1 A, an In-Ga-Zn oxide was deposited by a sputtering method using a target with In:Ga:Zn=4:2:4.1 [atomic ratio] and an In-Ga-Zn oxide was deposited by a sputtering method using a target with In:Ga:Zn=1:3:4 [atomic ratio], whereby a stacked-layer structure of two layers was formed as a third oxide (the oxide film 230C) to be the oxide 230c.

Next, for the sample 1 A, a silicon oxynitride film (the insulating film 250A) to be the insulator 250 was deposited.

Next, for the sample 1 A, a titanium nitride film was deposited as a conductive film (the conductive film 260A) to be the conductor 260a, over the silicon oxynitride film to be the insulator 250. Then, a tungsten film was deposited as a conductive film (the conductive film 260B) to be the conductor 260b. Note that the titanium nitride film and the tungsten film were successively formed.

Then, for the sample 1 A, the conductive film 260A, the conductive film 260B, the insulating film 250A, and the oxide film 230C were partly removed to form the conductor 260, the insulator 250, and the oxide 230c.

Subsequently, a plug electrically connected to the transistor 200, a film including a stacked-layer structure of an aluminum oxide film and a hafnium oxide film as a film to be the insulator 282, and a film including silicon oxynitride as a film to be the insulator 284 were deposited.

Through the above process, the 1st layer including the first transistor 200 was formed. Next, an interlayer film was formed between the first transistor and the second transistor.

As the interlayer film, a film having a stress in the direction opposite to the warpage direction of the 1st layer was deposited. That is, in the case where the total of stresses of all the films forming the 1st layer (also referred to as the total stress of the 1st layer) is a compressive stress, a layer having a tensile stress is used as the interlayer film. In the case where the total stress of the 1st layer is a tensile stress, a layer having a compressive stress is used as the interlayer film.

In this example, the total stress of the 1st layer was a compressive stress. Therefore, a layer having a tensile stress as the total stress was used as the interlayer film. Specifically, a silicon oxide film having a compressive stress and a silicon oxide film having a tensile stress were deposited to be stacked so that the thickness of the silicon oxide film having a tensile stress was larger than the thickness of the silicon oxide film having a compressive stress.

Next, a 2nd layer including the second transistor 200 was formed over the interlayer film. The 2nd layer was formed by process similar to that of the 1st layer.

Through the above process, the sample 1 A was fabricated.

### <Cross-sectional Observation of Sample 1 A and Evaluation Results of Transistor Characteristics>

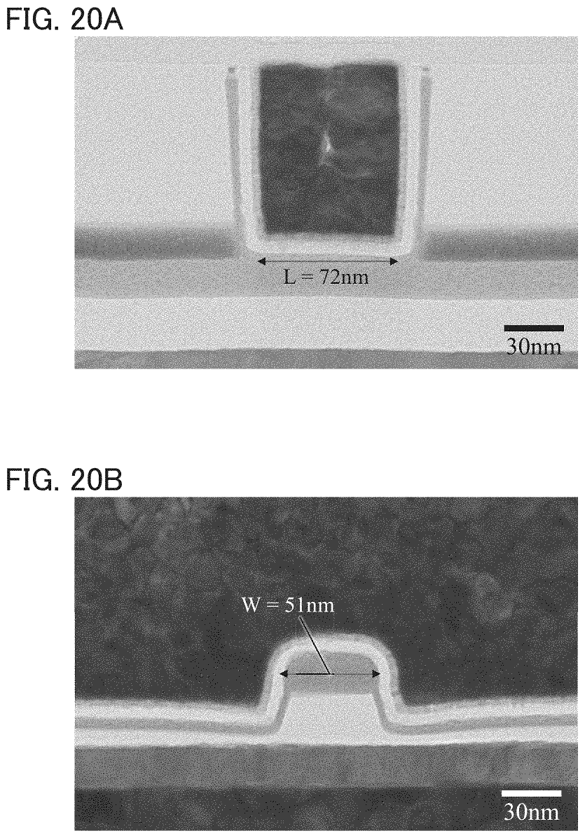

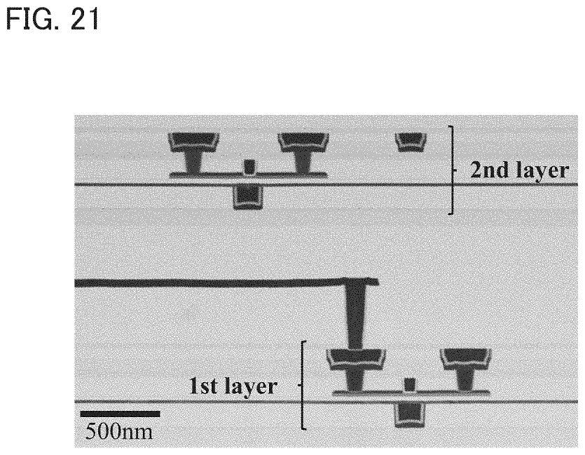

First, cross-sectional observation was performed on the sample 1 A. Note that the cross-sectional observation was performed with a scanning transmission electron microscope (STEM). As an apparatus for the observation, HD-2700 manufactured by Hitachi High-Technologies Corporation was used. FIG. 20 and FIG. 21 show cross-sectional STEM observation results.

As shown in FIG. 20A, the length of a channel portion of the sample 1 A in the L length direction was 72 nm. As shown in FIG. 20B, the length of the channel portion of the sample 1 A in the W length direction was51 nm. The stack of the first transistor and the second transistor was able to be fabricated as shown in FIG. 21.

Next, transistor characteristics of the sample 1 A were evaluated.

First, a change in the threshold value caused by a change in the voltage (Vbg) applied to the conductor 205 was confirmed in the transistor 200 of the 1st layer and the transistor 200 of the 2nd layer. Specifically, the confirmation was performed in such a manner that I_{d}-V_{g} measurement of the transistors 200 was performed on various conditions of the voltage (Vbg) applied to the conductor 205 of each transistor 200.

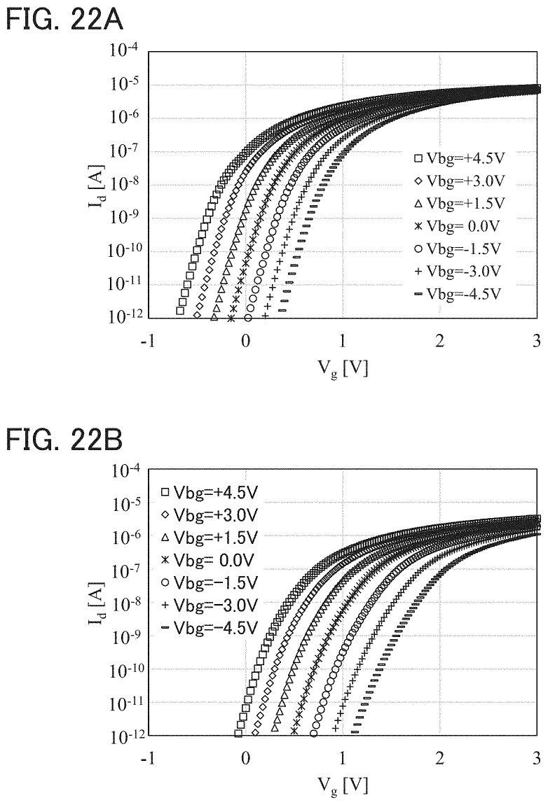

FIG. 22A shows the I_{d}-V_{g} measurement results of the transistor 200 of the 1st layer. FIG. 22B shows the I_{d}-V_{g} measurement results of the transistor 200 of the 2nd layer.

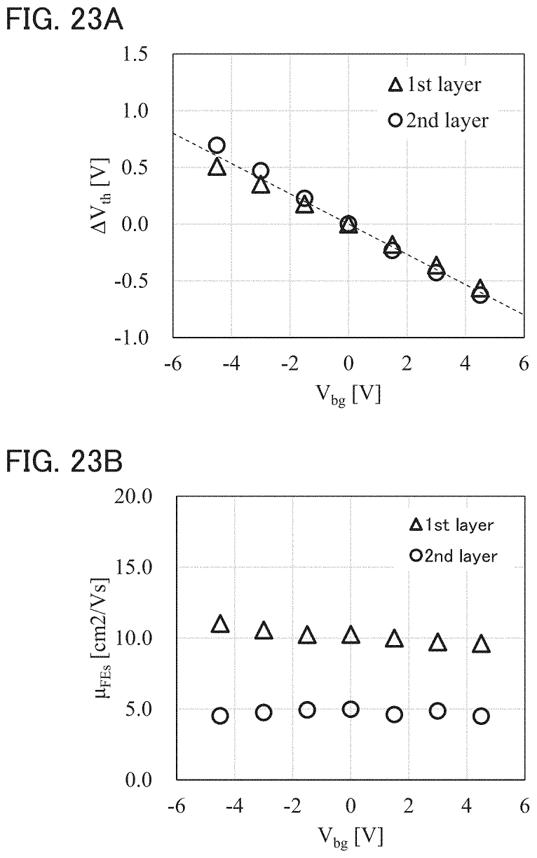

The amount of change in the threshold value with respect to the voltage (Vbg) applied to the conductor 205 of the transistor 200 provided in each layer was obtained using the results shown in FIG. 22. FIG. 23A shows the results. It was found that the threshold value of the transistor 200 was able to be controlled in accordance with the usage of the circuit by appropriately adjusting the voltage (V_{bg}) applied to the conductor 205, as shown in FIG. 23A.

Next, in the transistors of the 1st layer and the 2nd layer, influence of variation in the threshold value of each transistor 200 upon the field-effect mobility (μ_{FEs}) of each transistor 200 was examined. FIG. 23B shows the results. As shown in FIG. 23B, the amount of variation in the threshold value −∂Vₜₕ/∂V_{bg} is 0.13 V/V. It was found that the threshold value of each transistor 200 was varied by adjustment of the voltage (V_{bg}) applied to the conductor 205, while influence of the value of the voltage (Vbg) applied to the conductor 205 upon the field-effect mobility (μ_{FEs}) was small.

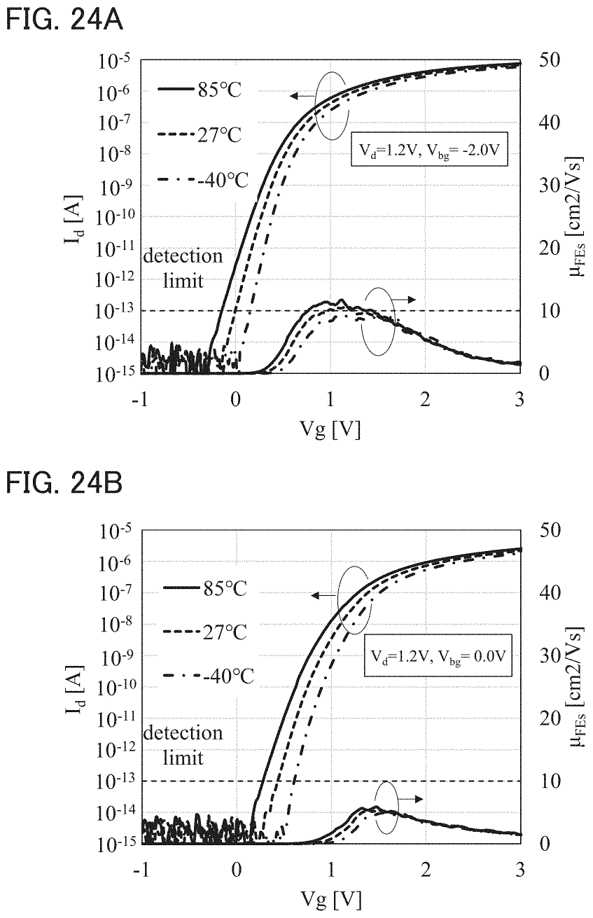

Subsequently, the temperature dependence of the transistor characteristics of the transistors 200 provided in the 1st layer and the 2nd layer was evaluated. The measurement conditions were set to −40° C., 27° C., and 85° C., and the transistor characteristics were measured with the semiconductor device operated under the condition temperatures. FIG. 24A shows I_{d}-V_{g} measurement results of the transistor 200 of the 1st layer. FIG. 24B shows I_{d}-V_{g} measurement results of the transistor 200 of the 2nd layer.

As shown in FIG. 24, it was found that off-leakage currents of the transistors 200 provided in the 1st layer and the 2nd layer were continuously lower than or equal to the lower detection limit (1×10⁻¹³A) in the temperature range of −40 to 85° C. The temperature dependence of the field-effect mobility of each transistor 200 is shown in the graph. It was verified that the field-effect mobility was hardly changed by the temperature change. This is an advantage that is not found in a Si transistor whose field-effect mobility is decreased under high temperatures.

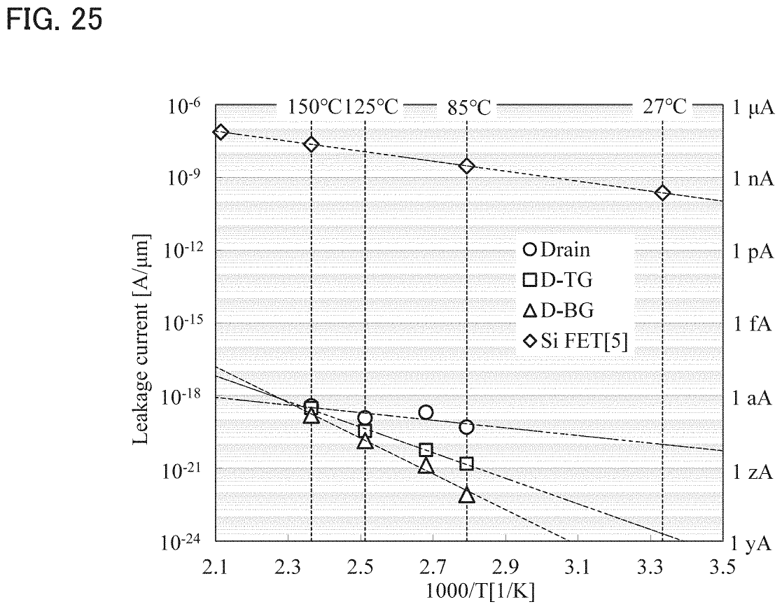

Next, in the transistor 200 of the 1st layer, off-leakage currents between the conductor 240a and the conductor 240b, between the conductor 240a and the conductor 260, and between the conductor 240a and the conductor 205 were measured in a high-temperature condition at 85° C. FIG. 25 shows the results. In FIG. 25, the vertical axis represents the leakage current, and the horizontal axis represents 1000/T. In addition, a white circle represents the drain, a square represents D-TG, a triangle represents D-BG, and a rhombus represents a result of a Si FET[5]. As shown in FIG. 25, the values of the off-leakage currents between the conductors were each lower than or equal to 5.0×10⁻²⁰A/μm. Accordingly, the off-leakage current of the transistor 200 was extremely low, indicating that it is possible to reduce a large amount of refresh power.

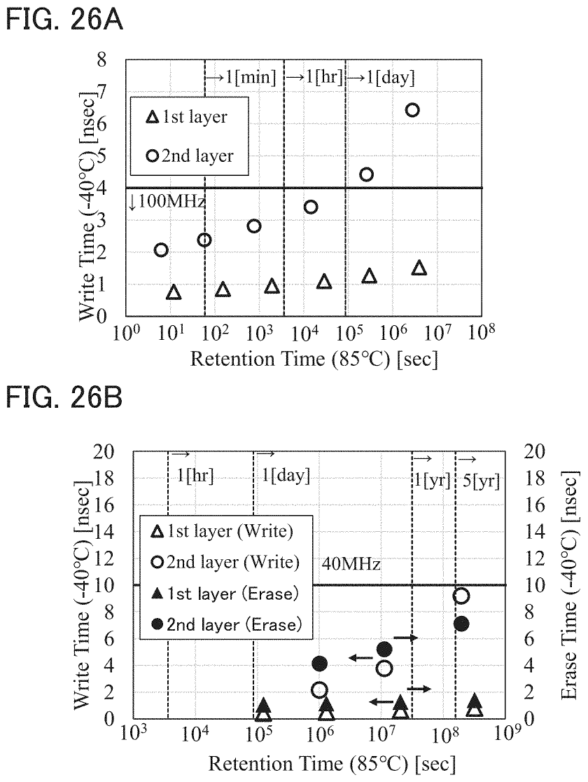

Next, a pseudo write speed was calculated in the case where a DOSRAM or a NOSRAM using the transistor 200 was assumed. FIG. 26 shows the results. In FIG. 26, the vertical axes represent a write time and an erase time, and the horizontal axis represents a retention time. FIG. 26A shows the results in the case where a DOSRAM was assumed, and FIG. 26B shows the results in the case where a NOSRAM was assumed. Note that the retention time was calculated from extrapolation of an I_{d}-V_{g} curve by subthreshold swing on the assumption that only subthreshold leakage was the cause of the leakage.

Note that on the assumption that the semiconductor device was used at higher than or equal to −40° C. and lower than or equal to 85° C., a data retention time at 85° C. where the off-leakage current had a maximum value was adjusted by application of the voltage (the V_{bg} voltage) to the conductor 205. Furthermore, power supply voltages used for retention and writing were set to −0.8 V/2.5 V, the amount of allowable voltage change was set to 0.2 V, a writing determination voltage was set to 0.52 V, and the operation speed of the driver circuit was set to 2.5 GHz.

As shown in FIG. 26A, at −40° C. where the write current had a minimum value, the write speed was able to be estimated at approximately 1.0 to 3.0 nsec in the case where the DOSRAM operation was assumed (in the case where a storage capacitance of 3.5 fF and a data retention time of one hour at 85° C. were assumed). This corresponds to 100 MHz or higher as the operation speed of the DOSRAM.

As shown in FIG. 26B, the write time was able to be estimated at 10.0 nsec or shorter in the case where the NOSRAM operation was assumed (in the case where a storage capacitance of 1.2 fF and a data retention time of five years at 85° C. were assumed). Note that in the case of the use in the NOSRAM, a load of a wiring such as a bit line can be reduced utilizing the stacked-layer structure; thus, influence of the reading speed is small, and the entire operation speed can be determined by the writing speed. Therefore, the case where the write time is 10.0 nsec or shorter corresponds to 40 MHz or higher as the operation speed.

FIG. 26B also shows estimation results of a time required for erasing written data. As the data erase time, a time required for reducing the voltage of the storage capacitance from Vd=1.08 V to 0.11 V (10% of 1.08 V) was estimated from the Id-Vd characteristics at Vs=0 V and Vg=2.25 V according to a procedure similar to that for the calculation of the write time. The data erase time was estimated at 2.0 nsec or shorter in the 1st layer.

FIG. 26B shows that the use of the semiconductor device with the stack of the transistors 200 for a memory cell enables both long-time retention and high-speed operation even in the case where either the DOSRAM operation or the NOSRAM operation is assumed.

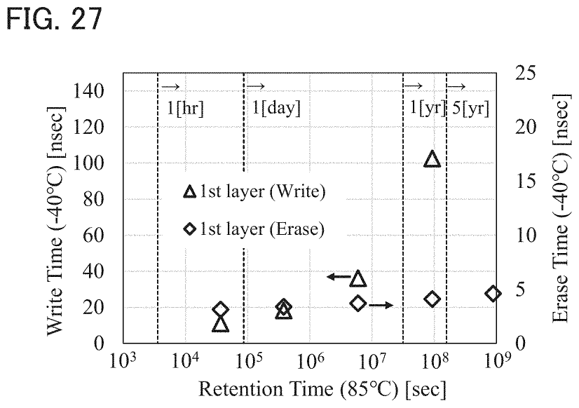

Next, FIG. 27 shows estimation results of a write time required for data:000 (V_{SN}=0.00 V) →data:111 (V_{SN}=90% of 1.08 V) and an erase time required for data:111 (V_{SN}=1.08 V) →data:000 (V_{SN}=10% of 1.08 V), which are estimated from static characteristics of the transistor 200 of the 1st layer in multilevel operation. In FIG. 27, the vertical axes represent the write time and the erase time and the horizontal axis represents the retention time.

The storage capacitance was set to 3.5 fF, and the allowable voltage change was set to 0.02 V in multilevel (3 bit/cell) retention. In the case where the use as the NOSRAM is assumed, an analog voltage can be written directly to a retention node, and therefore, verify operation is not required unlike in a flash memory. Therefore, the write time and the data erase time were both confirmed to be sufficiently shorter than 100 nsec, i.e., the write time of the driver circuit, for a retention time in a range of one year or shorter.

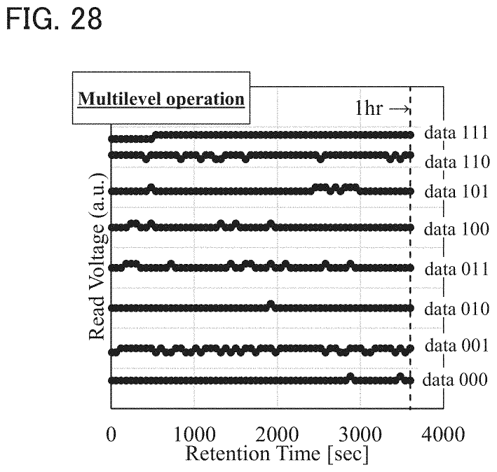

Next, write operation and a retention test were performed for the case where the sample 1 A functioned as a multilevel memory (in multilevel operation). In FIG. 28, the vertical axis represents a read voltage, the horizontal axis represents a retention time. FIG. 28 shows retention characteristics obtained from evaluation results. FIG. 28 indicates that 8-level-equivalent writing is possible for 100 nsec even in operation as a multilevel memory and that data can be retained for one hour or longer at 27° C.

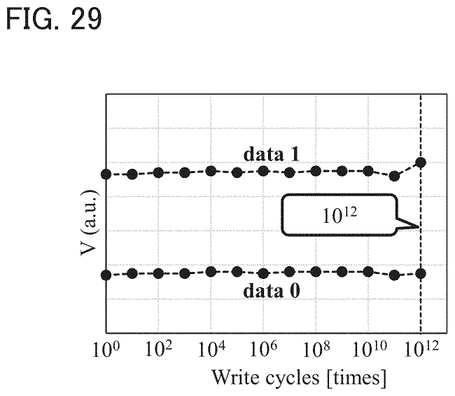

Subsequently, a rewrite endurance test in binary operation was performed in the case where the sample 1 A functioned as a NOSRAM memory cell at an environment temperature of 27° C. FIG. 29 shows rewrite endurance by the evaluation results. In FIG. 29, the horizontal axis represents write cycles. FIG. 29 shows that data can be retained without problem even when 10¹² or more times of rewrite operation are performed.

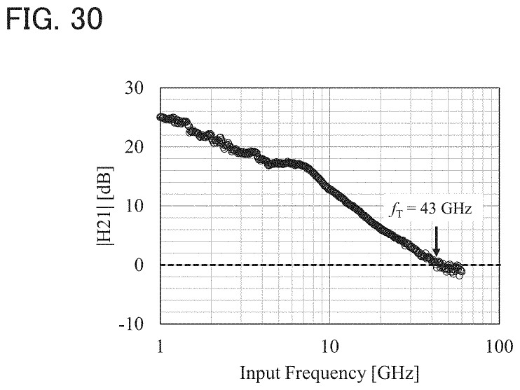

Here, the cutoff frequency f_{T} of the transistor 200 was evaluated. FIG. 30 shows the results. In FIG. 30, the horizontal axis represents input frequency. Note that in this evaluation, a sample in which only the 1st layer was formed was used. In the evaluation, the voltage (V_{g}) applied to the conductor 205 and the voltage (V_{d}) applied to the conductor 240a were each set to 2.5 V. As shown in FIG. 30, the cutoff frequency fT was able to be estimated at approximately 43 GHz. The results indicate that the transistor 200 can be applied not only to a memory but also to an analog circuit such as a high-frequency circuit.

At least part of this example can be implemented in combination with the other embodiments described in this specification as appropriate.

### REFERENCE NUMERALS

10: semiconductor device, 11: substrate, 12: adjustment layer, 14: layer, 16: adjustment layer, 18: layer, 20: semiconductor device, 21: substrate, 23: insulator, 24: layer, 26: adjustment layer, 27: insulator, 28: layer

1. A semiconductor device comprising:
a first layer provided with a first transistor comprising an oxide semiconductor, over a substrate;
a second layer over the first layer; and
a third layer provided with a second transistor comprising an oxide semiconductor, over the second layer,
wherein a total internal stress of the first layer and a total internal stress of the third layer act in a first direction, and
wherein a total internal stress of the second layer acts in a direction opposite to the first direction.

2. A semiconductor device comprising:
a first layer provided with a first transistor comprising an oxide semiconductor, over a substrate;
a second layer over the first layer;
a third layer provided with a second transistor comprising an oxide semiconductor, over the second layer;
a fourth layer between the first layer and the second layer; and
a fifth layer between the second layer and the third layer,
wherein a total internal stress of the first layer and a total internal stress of the third layer act in a first direction,
wherein a total internal stress of the second layer acts in a direction opposite to the first direction, and
wherein the fourth layer and the fifth layer each comprise a film having a barrier property.

3. The semiconductor device according to claim 2,
wherein a total internal stress of the fourth layer and a total internal stress of the fifth layer act in the first direction.

4. The semiconductor device according to claim 3,
wherein the film having the barrier property inhibits diffusion of hydrogen and an impurity.

5. The semiconductor device according to claim 2,
wherein the first layer is sealed with the fourth layer, and
wherein the third layer is sealed with the fifth layer.

6. The semiconductor device according to claim 1,
wherein the second layer comprises a conductor as a wiring.

7. The semiconductor device according to claim 1,
wherein the oxide semiconductor comprises indium, gallium, and zinc.

8. The semiconductor device according to claim 2,
wherein the second layer comprises a conductor as a wiring.

9. The semiconductor device according to claim 2,
wherein the oxide semiconductor comprises indium, gallium, and zinc.
